(19) United States
(12) Patent Application Publication
(10) Pub. No.: US 2026/0057929 A1
(43) Pub. Date: Feb. 26, 2026

(54) SEMICONDUCTOR MEMORY DEVICE AND MEMORY SYSTEM INCLUDING THE SAME

(71) Applicant: SAMSUNG ELECTRONICS CO., LTD., Suwon-si (KR)

(72) Inventors: Yejun KO, Suwon-si (KR); Myungkyu LEE, Suwon-si (KR); Kyomin SOHN, Suwon-si (KR); Kijun LEE, Suwon-si (KR); Eunae LEE, Suwon-si (KR); Sunghye CHO, Suwon-si (KR)

(73) Assignee: SAMSUNG ELECTRONICS CO., LTD., Suwon-si (KR)

(21) Appl. No.: 19/210,283

(22) Filed: May 16, 2025

(30) Foreign Application Priority Data
Aug. 22, 2024 (KR) 10-2024-0112507

(51) Int. Cl. G11C 11/4078; G11C 11/406; H01L 25/065; H01L 25/18; H10B 80/00

(52) U.S. Cl. CPC G11C 11/4078; G11C 11/40603; H01L 25/0657; H01L 25/18; H01L 2225/06513; H01L 2225/06541; H10B 80/00

(57) ABSTRACT

A semiconductor memory device includes a memory cell array including a plurality of memory cell rows, each row including a plurality of volatile memory cells, and a refresh control circuit including a hammer address register and is configured to perform a refresh operation on the plurality of memory cell rows. The refresh control circuit is further configured to receive a first active signal corresponding to a first active command received at a first time point, generate a counted value by counting active signals corresponding to active commands received until the first time point, generate a multiplied value based on a multiplication operation on the counted value and first upper bits corresponding to a portion of a random binary code, selectively store a first access row address corresponding to the first active command, and perform a hammer refresh operation, at a refresh timing, on one or more victim memory cell rows.

### CROSS-REFERENCE TO RELATED APPLICATIONS

This application claims benefit of priority under 35 U.S.C. § 119 to Korean Patent Application No. 10-2024-0112507, filed on Aug. 22, 2024, in the Korean Intellectual Property Office, the disclosure of which is incorporated by reference herein in its entirety.

### BACKGROUND

### 1. Field

The present disclosure relates generally to memories, and more particularly, to semiconductor memory devices that perform a hammer refresh operation and memory systems including the same.

### 2. Description of Related Art

A semiconductor memory device may be classified as a volatile memory device or a nonvolatile memory device. A volatile memory device may refer to a memory device that may lose data stored therein after losing power. As a non-limiting example of a volatile memory device, a dynamic random access memory (DRAM) may be used in various devices such as, but not limited to, a mobile system, a server, a graphic device, or the like.

However, related volatile memory devices (e.g., DRAM devices) may lose cell charges that may be stored in a memory cell due to several factors, including, but not limited to, a leakage current. In addition, when a word line is transitioned frequently between an active state and a precharged state (e.g., when the word line has been accessed intensively and/or frequently), an affected memory cell connected to a word line that is adjacent to the frequently accessed word line may lose stored charges. Charges stored in a memory cell may be maintained by recharging before data is lost by leakage of cell charges. Such recharge of cell charges may be referred to as a refresh operation, and a refresh operation may be performed repeatedly before cell charges are significantly lost.

### SUMMARY

One or more example embodiments of the present disclosure provide a semiconductor memory device capable of defending row hammer attack while reducing circuit complexity, when compared to related semiconductor memory devices.

Further, one or more example embodiments of the present disclosure provide a memory system capable of defending row hammer attack while reducing circuit complexity, when compared to related memory systems.

According to an aspect of the present disclosure, a semiconductor memory device includes a memory cell array including a plurality of memory cell rows, and a refresh control circuit configured to perform a refresh operation on the plurality of memory cell rows. Each row of the plurality of memory cell rows includes a plurality of volatile memory cells. The refresh control circuit includes a hammer address register. The refresh control circuit is further configured to receive a first active signal corresponding to a first active command received from an external memory controller at a first time point, generate a counted value by counting active signals corresponding to active commands received until the first time point, generate a multiplied value based on a multiplication operation on the counted value and first upper bits corresponding to a portion of a random binary code, selectively store, based on comparing the multiplied value with a reference value, a first access row address corresponding to the first active command in the hammer address register, and perform a hammer refresh operation, at a refresh timing, on one or more victim memory cell rows corresponding to a hammer address output from the hammer address register. The one or more victim memory cell rows are physically adjacent to a memory cell row from among the plurality of memory cell rows.

According to an aspect of the present disclosure, a semiconductor memory device includes a memory cell array including a plurality of memory cell rows, a refresh control circuit configured to perform a refresh operation on the plurality of memory cell rows, and a row hammer management circuit including a hammer address register. Each row of the plurality of memory cell rows includes a plurality of volatile memory cells. The row hammer management circuit is configured to receive a first active signal corresponding to a first active command received from an external memory controller at a first time point, generate a counted value by counting active signals corresponding active commands received until the first time point, generate a multiplied value based on multiplication operation on the counted value and first upper bits corresponding to a portion of a random binary code, selectively store, based on comparing the multiplied value with a reference value, a first access row address corresponding to the first active command in the hammer address register, and output a row address stored in the hammer address register to the refresh control circuit as a hammer address. The refresh control circuit is configured to perform a hammer refresh operation, at a refresh timing, on one or more victim memory cell rows corresponding to the hammer address. The one or more victim memory cell rows are physically adjacent to a memory cell row from among the plurality of memory cell rows.

According to an aspect of the present disclosure, a memory system includes a semiconductor memory device, and a memory controller configured to control the semiconductor memory device and to apply a refresh command to the semiconductor memory device. The semiconductor memory device includes a memory cell array including a plurality of memory cell rows, and a refresh control circuit configured to perform refresh operation on the plurality of memory cell rows. Each row of the plurality of memory cell rows includes a plurality of volatile memory cells. The refresh control circuit includes a hammer address register. The refresh control circuit is configured to receive a first active signal corresponding to a first active command received from the memory controller at a first time point, generate a counted value by counting active signals corresponding active commands received until the first time point, generate a multiplied value based on multiplication operation on the counted value and first upper bits corresponding to a portion of a random binary code, selectively store, based on comparing the multiplied value with a reference value, a first access row address corresponding to the first active command in the hammer address register, and store a first row address randomly selected from the first access row address in a hammer address queue as a first candidate hammer address, and perform a hammer refresh operation, at a refresh timing, on one or more victim memory cell rows corresponding to a hammer address output from the hammer address register. The one or more victim memory cell rows are physically adjacent to a memory cell row among the plurality of memory cell rows.

Therefore, in the semiconductor memory device and the memory system, according to example embodiments, the multiplier circuit in the hammer refresh circuit may generate a multiplied value including a sub multiplied value and an excess bit based on multiplication operation on counted value and first upper bits corresponding to a portion of the random binary code, and may selectively store a first access row address corresponding to a first access command in the hammer address register based on comparing the multiplied value with a reference value. Consequently, the semiconductor memory device may determine a hammer address based on a random pick while potentially reducing circuit complexity of the multiplier circuit.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram illustrating a memory system, according to example embodiments;

FIG. 2 is a block diagram illustrating the memory controller in FIG. 1, according to example embodiments;

FIG. 3 is a block diagram illustrating an example of the semiconductor memory device in FIG. 1, according to example embodiments;

FIG. 4 illustrates an example of the first bank array in the semiconductor memory device of FIG. 3, according to example embodiments;

FIG. 5 is a block diagram illustrating an example of the refresh control circuit in FIG. 3, according to example embodiments;

FIG. 6 is a block diagram illustrating an example of the hammer refresh circuit in the refresh control circuit of FIG. 5, according to example embodiments;

FIG. 7 is a circuit diagram illustrating an example of the random bit generator in FIG. 6, according to example embodiments;

FIG. 8 illustrates an example of the hammer address register in the hammer refresh circuit of FIG. 6, according to example embodiments;

FIG. 9A is a circuit diagram illustrating an example of the multiplier circuit in the hammer refresh circuit of FIG. 6, according to example embodiments;

FIG. 9B is a circuit diagram illustrating an example of the excess bit generator in the multiplier circuit of FIG. 9A, according to example embodiments;

FIG. 10 is a timing diagram of a hammer refresh performed by the semiconductor memory device, according to example embodiments,

FIG. 11 is a timing diagram of the semiconductor memory device determining a hammer address, according to example embodiments;

FIG. 12 is a diagram of an operation of the hammer address register, according to example embodiments;

FIG. 13 is a diagram of an operation of the hammer address register, according to example embodiments;

FIG. 14 is a timing diagram of a refresh operation performed by the semiconductor memory device, according to example embodiments;

FIG. 15 is a timing diagram of a refresh operation performed by the semiconductor memory device, according to example embodiments;

FIG. 16 is a diagram illustrating a portion of a memory cell array for describing generation of hammer refresh addresses, according to example embodiments;

FIG. 17 is a diagram illustrating a portion of a memory cell array during generation of hammer refresh addresses, according to example embodiments;

FIGS. 18, 19, and 20 are timing diagrams illustrating example operations of a refresh control circuit of FIG. 5, according to example embodiments;

FIG. 21 is a block diagram illustrating an example of the semiconductor memory device in FIG. 1, according to example embodiments

FIG. 22 is a block diagram illustrating an example of the row hammer management circuit in the semiconductor memory device of FIG. 21, according to example embodiments;

FIG. 23 is a block diagram illustrating an example of the refresh control circuit in FIG. 21, according to example embodiments;

FIG. 24 is a flow chart illustrating a method of operating a semiconductor memory device, according to example embodiments;

FIG. 25 is a block diagram illustrating a semiconductor memory device, according to example embodiments; and

FIG. 26 is a configuration diagram illustrating a semiconductor package including the stacked memory device, according to example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to”another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more. ” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

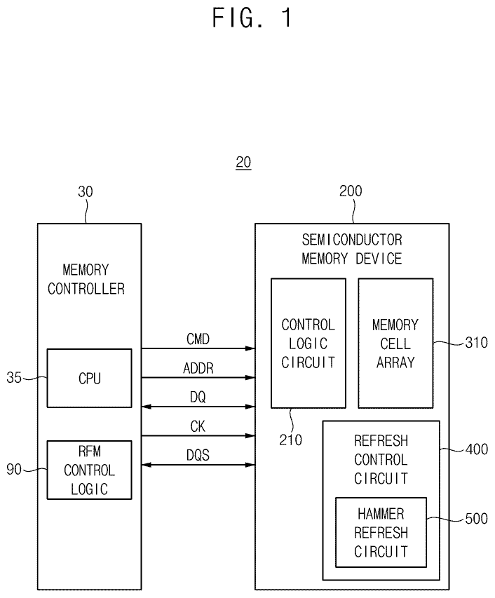

FIG. 1 is a block diagram illustrating a memory system, according to example embodiments.

Referring to FIG. 1, a memory system 20 may include a memory controller 30 and a semiconductor memory device 200.

The memory controller 30 may control overall operation of the memory system 20. The memory controller 30 may control overall data exchange between an external host and the semiconductor memory device 200. For example, the memory controller 30 may write data in the semiconductor memory device 200 and/or read data from the semiconductor memory device 200 in response to request from the external host.

In addition, the memory controller 30 may issue operation commands to the semiconductor memory device 200 for controlling the semiconductor memory device 200. In some example embodiments, the semiconductor memory device 200 may be and/or may include a memory device including dynamic memory cells such as, but not limited to, a dynamic random access memory (DRAM), double data rate (DDR) synchronous DRAM (SDRAM), a low power (LP) DDR SDRAM or the like.

The memory controller 30 may transmit a clock signal CK (e.g., the clock signal CK may also be referred to as a command clock signal), a command CMD, and an address (signal) ADDR to the semiconductor memory device 200. As used herein, for convenience of description, the terms clock signal CK, command CMD, and/or address ADDR and the terms clock signals CK, commands CMD, and/or addresses ADDR may be used interchangeably. The memory controller 30 may transmit a data strobe signal DQS to the semiconductor memory device 200 when the memory controller 30 writes data signal DQ in the semiconductor memory device 200. The semiconductor memory device 200 may transmit a data strobe signal DQS to the memory controller 30 when the memory controller 30 reads data signal DQ from the semiconductor memory device 200. The address ADDR may be accompanied by the command CMD and the address ADDR may be referred to as an access address.

The memory controller 30 may include a central processing unit (CPU) 35 that may control overall operation of the memory controller 30 and a refresh management (RFM) control logic 90 that may generate a refresh management command associated with a row hammer of the plurality of memory cell rows of the semiconductor memory device 200.

In an embodiment, the RFM control logic 90 may be physically implemented by analog and/or digital circuits including one or more of a logic gate, an integrated circuit, a microprocessor, a microcontroller, a memory circuit, a passive electronic component, an active electronic component, an optical component, and the like. For example, a field programmable gate array (FPGA) may be used to implement custom logic that may include the functionality of the RFM control logic 90. As another example, a processor in combination with a memory may be used to execute one or more instructions to perform the functionality of the RFM control logic 90. Alternatively or additionally, at least a portion of the functionality of the RFM control logic 90 may be incorporated into the CPU 35 and/or implemented as instructions to be executed by the CPU 35.

The semiconductor memory device 200 may include a memory cell array 310 that may store the data signal DQ, a control logic circuit 210, and a refresh control circuit 400. The refresh control circuit 400 may include a hammer refresh circuit 500.

The control logic circuit 210 may control operations of the semiconductor memory device 200. The memory cell array 310 may include a plurality of memory cell rows and each of the memory cell rows may include a plurality of memory cells (e.g., volatile memory cells).

The refresh control circuit 400 may control (e.g., perform) a normal refresh operation and/or a hammer refresh operation on the plurality of memory cell rows. The hammer refresh circuit 500 may receive a first active signal corresponding to a first active command received from the memory controller 30 at a first time point, may generate a counted value by counting active signals corresponding active commands received until the first time point, may generate a multiplied value based on multiplication operation on the counted value and first upper bits corresponding to a portion of a random binary code, may selectively store a first access row address corresponding to the first active command in a hammer address register therein based on comparing the multiplied value with a reference value, and may perform a hammer refresh operation, at a refresh timing, on one or more victim memory cell rows which are physically adjacent to a memory cell row among the plurality of memory cell rows, corresponding to a hammer address output from the hammer address register.

The control logic circuit 210, the refresh control circuit 400, and/or the hammer refresh circuit 500 may be physically implemented by analog and/or digital circuits including one or more of a logic gate, an integrated circuit, a microprocessor, a microcontroller, a memory circuit, a passive electronic component, an active electronic component, an optical component, and the like. For example, an FPGA may be used to implement custom logic that may include the functionality of the control logic circuit 210, the refresh control circuit 400, and/or the hammer refresh circuit 500. As another example, a processor in combination with a memory may be used to execute one or more instructions to perform at least a portion of the functionality of the control logic circuit 210, the refresh control circuit 400, and/or the hammer refresh circuit 500.

In example embodiment, the reference value may correspond to a maximum value of the random binary code.

The semiconductor memory device 200 may perform a refresh operation periodically due to charge leakage of memory cells storing data. For example, at least partially due to scale down of the manufacturing process of the semiconductor memory device 200, the storage capacitance of the memory cell may be decreased and the refresh period may be shortened. Alternatively or additionally, the refresh period may be further shortened because the entire refresh time may be increased as the memory capacity of the semiconductor memory device 200 is increased.

To compensate for degradation of adjacent memory cells due to the intensive access to a particular row or a hammer address, a target row refresh (TRR) scheme may be adopted and/or an in-memory refresh scheme may be developed to reduce the burden of the memory controller. The memory controller may be responsible for the hammer refresh operation in the TRR scheme and the semiconductor memory device may be responsible for the hammer refresh operation in the in-memory refresh scheme.

The chip size overhead for the in-memory refresh may be significant as the memory capacity may be increased and/or demands on low power consumption of the semiconductor memory device may be increased. Alternatively or additionally, the power consumption may be increased as the semiconductor memory device may perform the hammer refresh operation even when the memory cells are not subjected to intensive access. In addition, row hammering may occur in memory cells due to irregular (e.g., non-uniform) access patterns.

In the semiconductor memory device 200, according to example embodiments, instead of comparing the random binary code with a plurality of reference values, the hammer refresh circuit 500 may generate a multiplied value based on a multiplication operation on a counted value and first upper bits corresponding to a portion of the random binary code, and may selectively store a first access row address corresponding to a first access command in the hammer address register based on the comparing of the multiplied value with a reference value. Consequently, the semiconductor memory device 200 may determine a hammer address based on random pick while reducing circuit complexity of the hammer refresh circuit 500, when compared to related semiconductor memory devices.

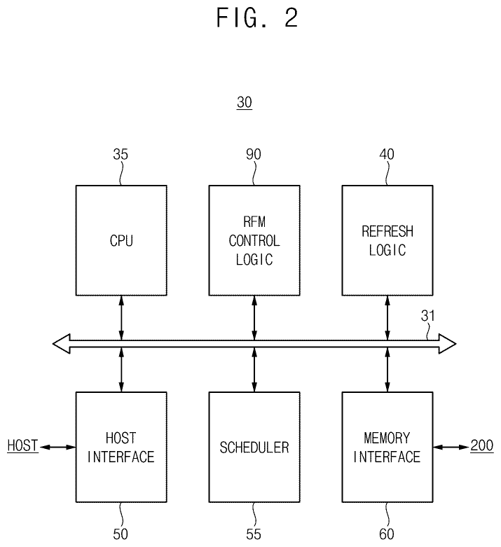

FIG. 2 is a block diagram illustrating the memory controller in FIG. 1, according to example embodiments.

Referring to FIG. 2, the memory controller 30 may include the CPU 35, the RFM control logic 90, a refresh logic 40, a host interface 50, a scheduler 55, and a memory interface 60 which may be connected to each other through a bus 31.

The CPU 35 may control overall operation of the memory controller 30. For example, the CPU 35 may control the RFM control logic 90, the refresh logic 40, the host interface 50, the scheduler 55, and/or the memory interface 60 through the bus 31.

The refresh logic 40 may generate an auto refresh command for refreshing memory cells of the plurality of memory cell rows based on a refresh interval of the semiconductor memory device 200.

The host interface 50 may perform interfacing with a host. The memory interface 60 may perform interfacing with the semiconductor memory device 200.

The scheduler 55 may manage scheduling and transmission of sequences of commands generated in the memory controller 30. The scheduler 55 may transmit an auto refresh command and the refresh management command to the semiconductor memory device 200 via the memory interface 60.

In an embodiment, the refresh logic 40 and/or the scheduler 55 may be physically implemented by analog and/or digital circuits including one or more of a logic gate, an integrated circuit, a microprocessor, a microcontroller, a memory circuit, a passive electronic component, an active electronic component, an optical component, and the like. For example, an FPGA may be used to implement custom logic that may include the functionality of the refresh logic 40 and/or the scheduler 55. As another example, a processor in combination with a memory may be used to execute one or more instructions to perform the functionality of the refresh logic 40 and/or the scheduler 55. Alternatively or additionally, at least a portion of the functionality of the refresh logic 40 and/or the scheduler 55 may be incorporated into the CPU 35 and/or implemented as instructions to be executed by the CPU 35.

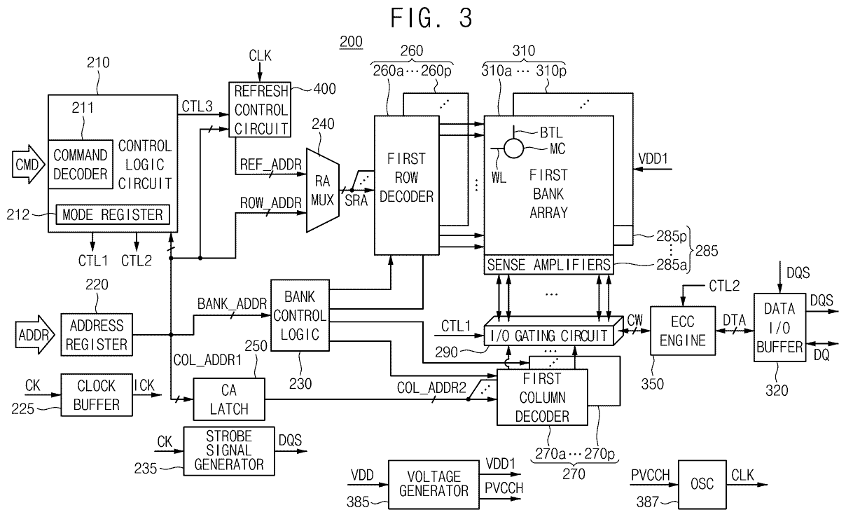

FIG. 3 is a block diagram illustrating an example of the semiconductor memory device in FIG. 1, according to example embodiments.

Referring to FIG. 3, the semiconductor memory device 200 may include the control logic circuit 210, an address register 220, a bank control logic 230, the refresh control circuit 400, a row address (RA) multiplexer 240, a column address (CA) latch 250, a plurality of row decoders 260 (e.g., a first row decoder 260a to a p-th row decoder 260p, where p is a positive integer greater than one (1)), a plurality of column decoders 270 (e.g., a first column decoder 270a to a p-th column decoder 270p), the memory cell array 310, a plurality of sense amplifiers 285 (e.g., a first sense amplifier 285a to p-th sense amplifier 285p), an input/output (I/O) gating circuit 290, an error correction code (ECC) engine 350, a clock buffer 225, a strobe signal generator 235, a voltage generator 385, an oscillator (OSC) 387, and a data I/O buffer 320.

The memory cell array 310 may include a plurality of bank arrays (e.g., a first bank array 310a to a p-th bank array 310p). The plurality of row decoders 260 may be respectively coupled to the plurality of first to p-th bank arrays 310a to 310p, the plurality of column decoders 270 may be respectively coupled to the plurality of first to p-th bank arrays 310a to 310p, and the plurality of sense amplifiers 285 may be respectively coupled to the plurality of first to p-th bank arrays 310a to 310p.

The plurality of first to p-th bank arrays 310a to 310p, the plurality of row decoders 260, the plurality of column decoders 270, and the plurality of sense amplifiers 285 may respectively form a plurality of banks (e.g., first to p-th banks). Each of the plurality of first to p-th bank arrays 310a to 310p may include a plurality of memory cells MC formed at intersections of a plurality of word lines WL and a plurality of bit lines BTL.

The address register 220 may receive the address ADDR that may include a bank address BANK_ADDR, a row address ROW_ADDR, and/or a column address COL_ADDR1 from the memory controller 30. The address register 220 may provide the received bank address BANK_ADDR to the bank control logic 230, may provide the received row address ROW_ADDR to the row address multiplexer 240 and the refresh control circuit 400, and may provide the received column address COL_ADDR1 to the column address latch 250.

The bank control logic 230 may generate bank control signals in response to the bank address BANK_ADDR. A row decoder of the plurality of row decoders 260 corresponding to the bank address BANK_ADDR may be activated in response to the bank control signals, and a column decoder of the plurality of column decoders 270 corresponding to the bank address BANK_ADDR may be activated in response to the bank control signals.

The row address multiplexer 240 may receive the row address ROW_ADDR from the address register 220, and may receive a refresh row address REF_ADDR from the refresh control circuit 400. The row address multiplexer 240 may selectively output the row address ROW_ADDR and/or the refresh row address REF_ADDR as a row address SRA. The row address SRA that is output from the row address multiplexer 240 may be applied to the plurality of row decoders 260.

The refresh control circuit 400 may sequentially increase and/or decrease the refresh row address REF_ADDR in a normal refresh mode in response to a third control signal CTL3 from the control logic circuit 210. The refresh control circuit 400, in a hammer refresh mode, may generate a random binary code based on a clock signal CLK and may output a hammer refresh address as a refresh row address. The hammer refresh address may be and/or may include addresses of one or more victim memory cell rows that may be disposed physically adjacent to a memory cell row corresponding to a hammer address.

The activated one of the plurality of row decoders 260, by the bank control logic 230, may decode the row address SRA that may be output from the row address multiplexer 240, and may activate a word line corresponding to the row address SRA. For example, the activated bank row decoder may apply a word line driving voltage to the word line corresponding to the row address.

The column address latch 250 may receive the column address COL_ADDR1 from the address register 220, and may temporarily store the received column address COL_ADDR1. In some embodiments, in a burst mode, the column address latch 250 may a generate column address COL_ADDR2 that increments from the received column address COL_ADDR1. The column address latch 250 may apply the temporarily stored and/or generated column address COL_ADDR2 to the plurality of column decoders 270a to 270p.

The activated one of the plurality of column decoders 270 may activate a sense amplifier corresponding to the bank address BANK_ADDR and the column address COL_ADDR1 through the I/O gating circuit 290.

The I/O gating circuit 290 may include a circuitry for gating input/output (I/O) data, and may further include input data mask logic, read data latches for storing data that may be output from the plurality of first to p-th bank arrays 310a to 310p, and may write drivers for writing data to the plurality of first to p-th bank arrays 310a to 310p.

A codeword CW read from a selected bank array from among the plurality of first to p-th bank arrays 310a to 310p may be sensed by a sense amplifier 285 coupled to the selected bank array from which the data is to be read, and may be stored in the read data latches. The codeword CW stored in the read data latches may be provided to the data I/O buffer 320 as data DTA after ECC decoding has been performed on the codeword CW by the ECC engine 350. The data I/O buffer 320 may convert the data DTA into the data signal DQ, and may transmit the data signal DQ along with the data strobe signal DQS to the memory controller 30.

The data signal DQ to be written in a selected bank array from among the plurality of first to p-th bank arrays 310a to 310p may be provided to the data I/O buffer 320 from the memory controller 30. The data I/O buffer 320 may convert the data signal DQ to the data DTA, and may provide the data DTA to the ECC engine 350. The ECC engine 350 may perform an ECC encoding on the data DTA to generate parity bits, and the ECC engine 350 may provide the codeword CW including data DTA and the parity bits to the I/O gating circuit 290. The I/O gating circuit 290 may write the codeword CW in a sub-page in the selected bank array through the write drivers.

The data I/O buffer 320 may provide the data signal DQ from the memory controller 30 to the ECC engine 350 by converting the data signal DQ to the data DTA in a write operation of the semiconductor memory device 200, may convert the data DTA to the data signal DQ from the ECC engine 350, and may transmit the data signal DQ and the data strobe signal DQS to the memory controller 30 in a read operation of the semiconductor memory device 200.

The ECC engine 350 may perform an ECC encoding on the data DTA and may perform an ECC decoding on the codeword CW based on a second control signal CTL2 from the control logic circuit 210.

The clock buffer 225 may receive the clock signal CK, may generate an internal clock signal ICK by buffering the clock signal CK, and may provide the internal clock signal ICK to circuit components processing the command CMD and/or the address ADDR.

The strobe signal generator 235 may receive the clock signal CK, may generate the data strobe signal DQS based on the clock signal CK and may provide the data strobe signal DQS to the data I/O buffer 320.

The voltage generator 385 may generate an operating voltage VDD1 based on a power supply voltage VDD received from an outside device, may generate a power stabilizing signal PVCCH indicating that the power supply voltage VDD has reached a reference voltage level, may provide the operating voltage VDD1 to the memory cell array 310, and may provide the power stabilizing signal PVCCH to the oscillator 387.

The oscillator 387 may generate the clock signal CLK toggling periodically based on the power stabilizing signal PVCCH and may provide the clock signal CLK to the refresh control circuit 400.

The refresh control circuit 400 may generate the random binary code based on the clock signal CLK, may generate the multiplied value based on multiplication operation on the counted value and first upper bits corresponding to a portion of the random binary code, and may selectively store the first access row address corresponding to a first access command received at the first time point in the hammer address register based on comparing the multiplied value with a reference value. Consequently, the semiconductor memory device 200 may determine a hammer address (and/or may perform a hammer refresh operation) based on a random pick while reducing circuit complexity of the hammer refresh circuit 500, when compared to related semiconductor memory devices.

The control logic circuit 210 may control operations of the semiconductor memory device 200. For example, the control logic circuit 210 may generate control signals for the semiconductor memory device 200 in order to perform a write operation, a read operation, a normal refresh operation and a hammer refresh operation. The control logic circuit 210 may include a command decoder 211 that may decode the command CMD received from the memory controller 30 and a mode register 212 that may set an operation mode of the semiconductor memory device 200.

For example, the command decoder 211 may generate the control signals corresponding to the command CMD by decoding a write enable signal, a row address strobe signal, a column address strobe signal, a chip select signal, or the like. The control logic circuit 210 may generate a first control signal CTL1 to control the I/O gating circuit 290, the second control signal CTL2 to control the ECC engine 350, and the third control signal CTL3 to control the refresh control circuit 400.

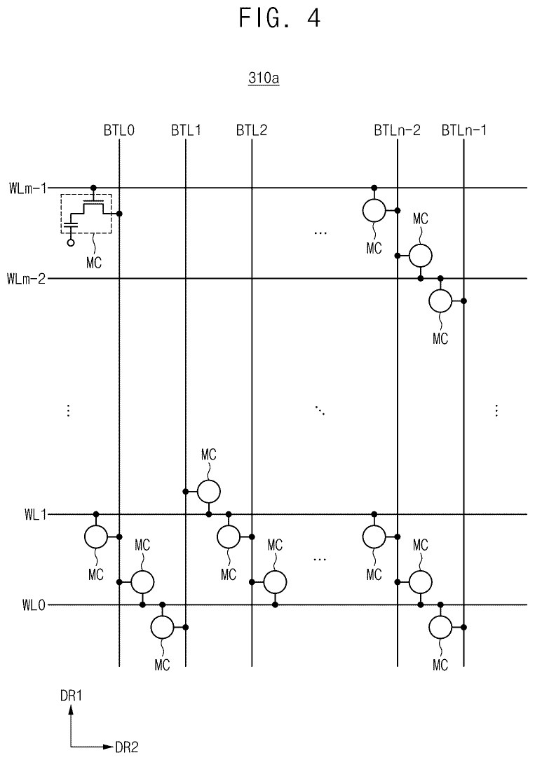

FIG. 4 illustrates an example of the first bank array in the semiconductor memory device of FIG. 3, according to example embodiments.

Referring to FIG. 4, the first bank array 310a may include a plurality of word lines WL (e.g., a first word line WL0, a second word line WL1, to an (m−1)-th word line WL(m−2), and an m-th word line WLm−1, where m is a positive integer greater than two (2)), a plurality of bit lines BTL (e.g., a first bit line BTL0, a second bit line BTL1, a third bit line BTL2, to an (n−1)-th bit line BTLn−2, and an n-th bit line BLn−1, where n is a positive integer greater than two (2)), and a plurality of memory cells MCs disposed at intersections between the plurality of word lines WL and the plurality of bit lines BTL. Each of the memory cells MCs may include a cell transistor coupled to each of the plurality of word lines WL and each of the plurality of bit lines BTL, and a cell capacitor coupled to the cell transistor. Each of the plurality of memory cells MCs may have a DRAM cell structure. Each of the plurality of word lines WL may extend in a first direction DR1 and each of the plurality of bit lines BTL may extend in a second direction DR2 crossing the first direction DR1.

The plurality of word lines WL coupled to the plurality of memory cells MCs may be referred to as rows of the first bank array 310a and the plurality of bit lines BTL coupled to the plurality of memory cells MCs may be referred to as columns of the first bank array 310a.

Although FIG. 4 illustrates an example embodiment of the first bank array 310a, the present disclosure is not limited in this regard. For example, in operation, the structure of the first bank array 310a may differ from the embodiments illustrated in FIG. 4. That is, the first bank array 310a may have less word lines, more word lines, less bit lines, more bit lines, or the like. In addition, the embodiments described with reference to FIG. 4 may be similarly applied to other bank arrays of the plurality of first to p-th bank arrays 310a to 310p described above with reference to FIG. 3. Alternatively or additionally, at least two bank arrays from among the plurality of first to p-th bank arrays 310a to 310p may have different structures.

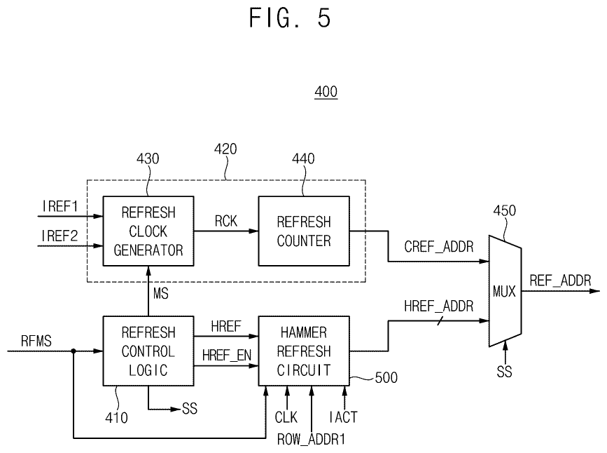

FIG. 5 is a block diagram illustrating an example of the refresh control circuit in FIG. 3, according to example embodiments.

Referring to FIG. 5, the refresh control circuit 400 may include a refresh control logic 410, a normal refresh circuit 420, a hammer refresh circuit 500, and a multiplexer (MUX) 450.

The refresh control logic 410, based on a refresh management signal RFMS, may provide a mode signal MS to the normal refresh circuit 420, and may provide the hammer refresh circuit 500 with a hammer refresh enable signal HREF_EN, and a hammer refresh signal HREF to control output timing of the hammer address. In addition, the refresh control logic 410 may generate a selection signal SS based on the refresh management signal RFMS and may provide the selection signal SS to the multiplexer 450.

The refresh control logic 410 may provide the normal refresh circuit 420 with the mode signal MS designating the normal refresh mode or the hammer refresh mode based on the refresh management signal RFMS. The refresh management signal RFMS may be generated by the control logic circuit 210 based on a refresh command from the memory controller 30. The refresh management signal RFMS may be included in the third control signal CTL3 of FIG. 3.

The normal refresh circuit 420 may include a refresh clock generator 430 and a refresh counter 440.

The refresh clock generator 430 may generate a refresh clock signal RCK indicating a timing of a normal refresh operation based on a first refresh signal IREF1, a second refresh signal IREF2, and the mode signal MS. The refresh clock generator 430 may generate the refresh clock signal RCK in response to the receiving the first refresh signal IREF1 or during the second refresh signal IREF2 is activated.

When the command CMD from the memory controller 30 corresponds to an auto refresh command, the control logic circuit 210 in FIG. 3 may apply the first refresh signal IREF1 to the refresh control circuit 400 whenever the control logic circuit 210 receives the auto refresh command. When the command CMD from the memory controller 30 corresponds to a self-refresh entry command, the control logic circuit 210 may apply the second refresh signal IREF2 to the refresh control circuit 400 and the second refresh signal IREF2 may be activated from a time point when the control logic circuit 210 receives the self-refresh entry command to a time point when control logic circuit 210 receives a self-refresh exit command.

The refresh counter 440 may generate a counter refresh address CREF_ADDR designating sequentially the memory cell rows by performing counting operation at the period of the refresh clock signal RCK, and may provide the counter refresh address CREF_ADDR to the multiplexer 450.

The hammer refresh circuit 500 may receive the clock signal CLK and an active signal IACT. The clock signal CLK may be provided from the oscillator 387 of FIG. 3, and the control logic circuit 210 may apply the active signal to the hammer refresh circuit 500 whenever the control logic circuit 210 receives an active command from the memory controller 30.

The hammer refresh circuit 500 may receive a first active signal corresponding to a first active command from the memory controller 30 at a first time point, may generate a counted value by counting active signals corresponding active commands received until the first time point, may generate a multiplied value based on multiplication operation on the counted value and first upper bits corresponding to a portion of a random binary code generated based on the clock signal CLK, may selectively store a first access row address ROW_ADDR1 corresponding to the first active command in a hammer address register therein based on comparing the multiplied value with a reference value may generate hammer refresh addresses HREF_ADDR designating one or more victim memory cell rows which are physically adjacent to a memory cell row among the plurality of memory cell rows, corresponding to a hammer address output from the hammer address register and may provide the generate hammer refresh addresses HREF_ADDR to the multiplexer 450. The hammer refresh circuit 500 may further receive the refresh management signal RFMS.

The multiplexer 450 may output one of the counter refresh address CREF_ADDR and the hammer refresh addresses HREF_ADDR as the refresh row address REF_ADDR, based on the selection signal SS.

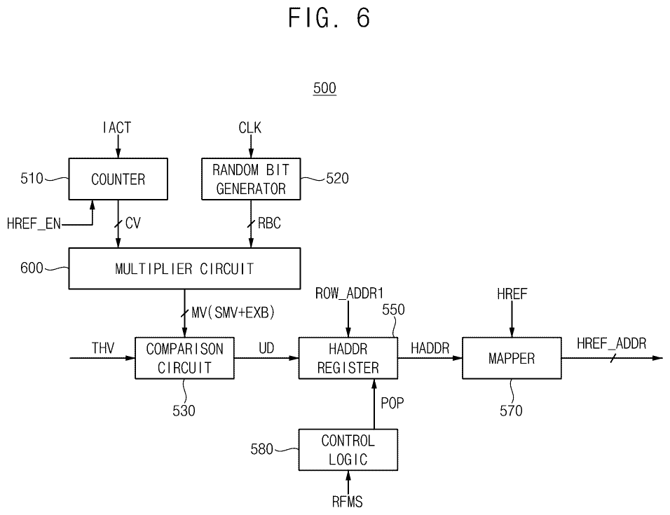

FIG. 6 is a block diagram illustrating an example of the hammer refresh circuit in the refresh control circuit of FIG. 5, according to example embodiments.

Referring to FIG. 6, the hammer refresh circuit 500 may include a counter 510, a random bit generator 520, a multiplier circuit 600, a comparison circuit 530, a hammer address (HADDR) register 550, a mapper 570, and a control logic 580.

The counter 510 may generate a counted value CV by counting the active signals IACT received until the first time point. The random bit generator 520 may generate a random binary code RBC based on the clock signal CLK.

In example embodiment, the random binary code RBC may include M bits and the counted value CV may include N bits. As used herein, M may refer to a positive integer that is greater than two (2), and N may refer to a positive integer that is less than M.

The multiplier circuit 600 may generate a multiplied value MV based on multiplication operation on the counted value CV and first upper bits corresponding to a portion of the random binary code RBC. The multiplied value MV may be referred to as an operated value. The multiplier circuit 600 may generate a sub multiplied value SMV by performing the multiplication operation on the counted value CV and the first upper bits of the random binary code RBC, may generate an excess bit EXB by performing operation on second upper bits corresponding to a portion of the first upper bits and third upper bits of the counted value CV and may provide the comparison circuit 530 with the sub multiplied value SMV and the excess bit EXB as the multiplied value MV.

The comparison circuit 530 may receive the multiplied value MV including the sub multiplied value SMV and the excess bit EXB, may compare the multiplied value MV with a reference value THV, may generate an updating signal UD based on a result of the comparison, and may provide the updating signal UD to the hammer address register 550.

The hammer address register 550 may selectively store a first access row address ROW_ADDR1 received at the first time point, therein, based on a logic level of the updating signal UD.

The mapper 570 may receive the hammer address HADDR output from the hammer address register 550 and may output the hammer refresh addresses HREF_ADDR designating addresses of the one or more victim memory cell rows based on the hammer refresh signal HREF.

The control logic 580 may provide a pop signal POP to the hammer address register 550 based on the refresh management signal RFMS and the hammer address register 550 may output, to the mapper 570, the hammer address HADDR stored therein based on the pop signal POP.

According to example embodiments, complexity of the multiplier circuit 600 may be reduced, when compared to related multiplier circuits, since the multiplier circuit 600, instead of performing a multiplication operation on entire bits of the random binary code RBC, may generate the multiplied value MV including the sub multiplied value SMV and the excess bit EXB by performing the multiplication operation on the counted value CV and the first upper bits corresponding to a portion of the random binary code RBC.

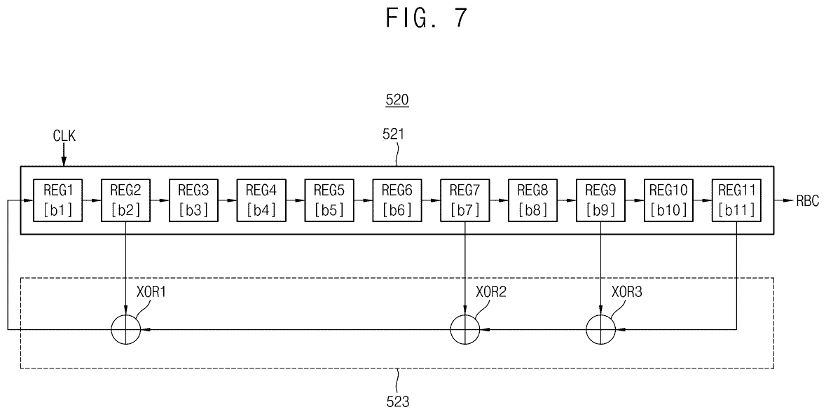

FIG. 7 is a circuit diagram illustrating an example of the random bit generator in FIG. 6, according to example embodiments.

Referring to FIG. 7, the random bit generator 520 may include a register circuit 521 and a logical operation circuit 523. In example embodiments, the random bit generator 520 may be implemented with a linear feedback shift register. That is, the register circuit 521 and the logical operation circuit 523 may constitute a linear feedback shift register.

The linear feedback shift register may determine feedback bits based on a characteristic polynomial having a coefficient equal to zero (0) and/or one (1). However, the present disclosure is not limited in this regard, and the feedback bits may have other values. The feedback bits may be output through a feedback path of the linear feedback shift register and bits, generated by logical operation based on the feedback bits, may be input to input terminals of the linear feedback shift register. The linear feedback shift register may generate a pseudo random sequence based on the bits input to the input terminals.

For example, when the random bit generator 520 is implemented based on a characteristic polynomial of x¹¹+x⁹+x⁷+x²+1 as illustrated in FIG. 7, the register circuit 521 may include a plurality of registers (e.g., a first register REG1, a second register REG2, a third register REG3, a fourth register REG4, a fifth register REG5, a sixth register REG6, a seventh register REG7, an eighth register REG8, a ninth register REG9, a tenth register REG10, and an eleventh register REG11) and the logical operation circuit 523 may include a plurality of logic circuits (e.g., a first logic circuit XOR1, a second logic circuit XOR2, and a third logic circuit XOR3).

For example, each of the plurality of first to eleventh registers REG1 to REG11 may store a respective bit of a plurality of bits (e.g., a first bit b1, a second bit b2, a third bit b3, a fourth bit b4, a fifth bit b5, a sixth bit b6, a seventh bit b7, an eighth bit b8, a ninth bit b9, a tenth bit b10, and an eleventh bit b11). Values of the plurality of first to eleventh bits b1-b11 may vary according to a shift operation. Each of the plurality of first to third logic circuits XOR1 to XOR3 may perform exclusive OR operations.

The random bit generator 520 may output the random binary code RBC through the register circuit 521. The random bit generator 520 may output the random binary code RBC having a predetermined number of bits. For example, the random bit generator 520 may output the random binary code RBC having five (5) bits based on the first to fifth bits b1 to b5 stored in the first to fifth registers REG1 to REG5.

The logical operation circuit 523 may be positioned in a feedback path of the random bit generator 520. The first logical circuit XOR1 may be positioned in an output path of the second register REG2, the second logical circuit XOR2 may be positioned in an output path of the seventh register REG7, and the third logical circuit XOR3 may be positioned in output paths of the ninth register REG9 and the eleventh register REG11.

For example, the third logical circuit XOR3 may perform a logical operation based on the ninth bit b9 in the ninth register REG9 and the eleventh bit b11 in the eleventh register REG11. The second logical circuit XOR2 may perform a logical operation based on the seventh bit b7 in the seventh register REG7 and an output of the third logical circuit XOR3. The first logical circuit XOR1 may perform a logical operation based on the second bit b2 in the second register REG1 and an output of the second logical circuit XOR2.

The output of the first logical circuit XOR1 may vary based on the second bit b2, the seventh bit b7, the ninth bit b9 and the eleventh bit b11. That is, each of the second bit b2, the seventh bit b7, the ninth bit b9 and the eleventh bit b11 may be a feedback bit. The output of the output of the first logical circuit XOR1 may be provided to the first register REG1 as an input.

The first register REG1 may store the output of the first logical circuit XOR1 as the first bit b1. The bit input through a feedback path may be shifted through the plurality of first to eleventh registers REG1 to REG11 based on the clock signal CLK.

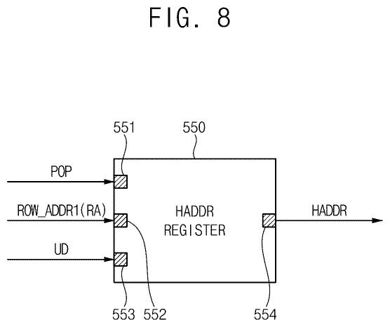

FIG. 8 illustrates an example of the hammer address register in the hammer refresh circuit of FIG. 6, according to example embodiments.

Referring to FIG. 8, the hammer address register 550 may include a plurality of terminals (e.g., a first terminal 551, a second terminal 552, a third terminal 553, and a fourth terminal 554). The hammer address register 550 may store the access row address. Queue size of the hammer address register 550 may be one (1) and the hammer address register 550 may store one (1) access row address.

The hammer address register 550 may receive the pop signal POP, the first access row address ROW_ADDR1, and the updating signal UD. The hammer address register 550 may receive the pop signal POP through the first terminal 551, may receive the first access row address ROW_ADDR1 through the second terminal 552, and may receive the updating signal UD through the third terminal 553.

The first access row address ROW_ADDR1 may correspond to the first active command.

The hammer address register 550 may selectively store the first access row address ROW_ADDR1 based on a logic level of the updating signal UD.

In response to the updating signal UD having a first logic level (e.g., a logic high level), the hammer address register 550 may store the first access row address ROW_ADDR1 therein. In response to the updating signal UD having a second logic level (e.g., a logic low level), the hammer address register 550 may maintain a register address that may be pre-stored instead of storing the first access row address ROW_ADDR1 therein. That is, in response to the updating signal UD having a first logic level, the hammer address register 550 may update the register address that may be pre-stored therein with the first access row address ROW_ADDR1.

The hammer address register 550 may determine whether to output the register address stored therein based on the pop signal POP. In response to the pop signal POP having a first logic level, the hammer address register 550 may output the register address as the hammer address HADDR. In response to the pop signal POP having a second logic level, the hammer address register 550 may not output the register address. The hammer address register 550 may continuously maintain and/or update the register address until receiving the pop signal POP having a first logic level.

The hammer address register 550 may output the register address as the hammer address HADDR through the fourth terminal 554. The hammer address register 550 may provide the hammer address HADDR to the mapper 570 in FIG. 6.

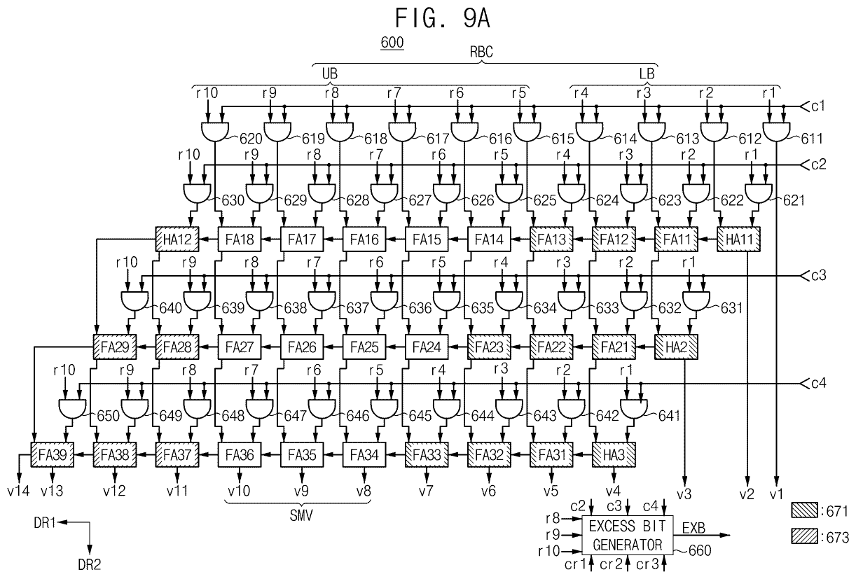

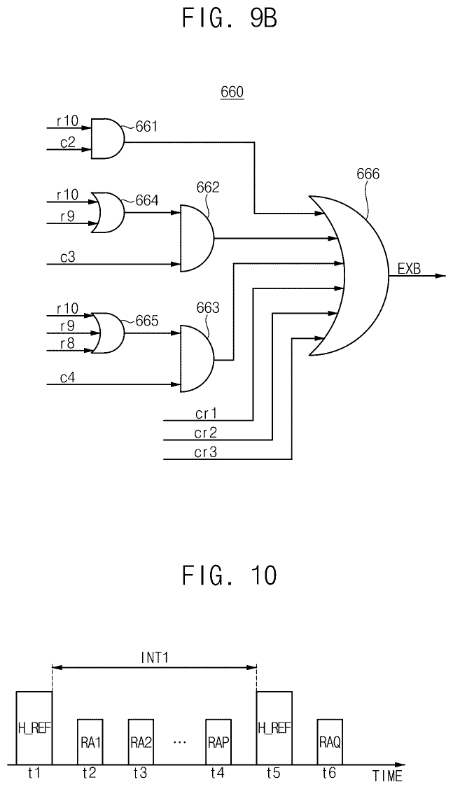

FIG. 9A is a circuit diagram illustrating an example of the multiplier circuit in the hammer refresh circuit of FIG. 6, according to example embodiments.

In FIG. 9A, assuming that the counted value CV includes a plurality of bits (e.g., a first counted value bit c1, a second counted value bit c2, a third counted value bit c3, and a fourth counted value bit c4, and the random binary code RBC includes a plurality of bits (e.g., a first random value bit r1, a second random value bit r2, a third random value bit r3, a fourth random value bit r4, a fifth random value bit r5, a sixth random value bit r6, a seventh random value bit r7, an eighth random value bit r8, a ninth random value bit r9, and a tenth random value bit r10).

The plurality of random value bits r1 to r10 of the random binary code RBC may be divided into lower bits LB and upper bits UB, the lower bits LB may include the first to fourth random value bits r1 to r4, and the upper bits UB may include bits the fifth to tenth random value bits r5 to r10. The upper bits UB may be referred to as first upper bits.

Referring to FIG. 9A, the multiplier circuit 600 may include a plurality of first AND gates (e.g., a first AND gate 611, a second AND gate 612, a third AND gate 613, a fourth AND gate 614, a fifth AND gate 615, a sixth AND gate 616, a seventh AND gate 617, an eighth AND gate 618, a ninth AND gate 619, and a tenth AND gate 620), a plurality of second AND gates (e.g., an eleventh AND gate 621, a twelfth AND gate 622, a thirteenth AND gate 623, a fourteenth AND gate 624, a fifteenth AND gate 625, a sixteenth AND gate 626, a seventeenth AND gate 627, an eighteenth AND gate 628, a nineteenth AND gate 629, and a twentieth AND gate 630), a plurality of third AND gates (e.g., a twenty-first AND gate 631, a twenty-second AND gate 632, a twenty-third AND gate 633, a twenty-fourth AND gate 634, a twenty-fifth AND gate 635, a twenty-sixth AND gate 636, a twenty-seventh AND gate 637, a twenty-eighth AND gate 638, a twenty-ninth AND gate 639, and a thirtieth AND gate 640), and plurality of fourth AND gates (e.g., a forty-first AND gate 641, a forty-second AND gate 642, a forty-third AND gate 643, a forty-fourth AND gate 644, a forty-fifth AND gate 645, a forty-sixth AND gate 646, a forty-seventh AND gate 647, a forty-eighth AND gate 648, a forty-ninth AND gate 649, and a fiftieth AND gate 650). The multiplier circuit 600 may further include a plurality of first adders (e.g., a first adder HA11, a second adder FA11, a third adder FA12, a fourth adder FA13, a fifth adder FA14, a sixth adder FA15, a seventh adder FA16, an eighth adder FA17, a ninth adder FA18, and a tenth adder HA12), a plurality of second adders (e.g., an eleventh adder HA2, a twelfth adder FA21, a thirteenth adder FA22, a fourteenth adder FA23, a fifteenth adder FA24, a sixteenth adder FA25, a seventeenth adder FA26, an eighteenth adder FA27, a nineteenth adder FA28, and a twentieth adder FA29), a plurality of third adders (e.g., a twenty-first adder FA3, a twenty-second adder FA31, a twenty-third adder FA32, a twenty-fourth adder FA33, a twenty-fifth adder FA34, a twenty-sixth adder FA35, a twenty-seventh adder FA36, a twenty-eighth adder FA37, a twenty-ninth adder FA38, and a thirtieth adder FA39), and an excess bit generator 660. In FIG. 9A, HA may denote a half adder and FA may denote a full adder.

Hatched adders represented by a reference numeral 671 and hatched adders represented by a reference numeral 673 may not be included in the multiplier circuit 600 and/or may not be associated with multiplication operation.

Operation of a related multiplier circuit is described with reference to FIG. 9A. In the related multiplier circuit, each of the plurality of first AND gates 611 to 620 may perform an AND operation on the first counted value bit c1 of the counted value CV and respective bits of the first to tenth random value bits r1 to r10 of the random binary code RBC, each of the plurality of second AND gates 621 to 630 may perform an AND operation on the second counted value bit c2 of the counted value CV and respective bits of the first to tenth random value bits r1 to r10 of the random binary code RBC, each of the plurality of third AND gates 631 to 640 may perform an AND operation on the third counted value bit c3 of the counted value CV and respective bits of the first to tenth random value bits r1 to r10 of the random binary code RBC, and each of the plurality of fourth AND gates 641 to 650 may perform an AND operation on the fourth counted value bit c4 of the counted value CV and respective bits of the first to tenth random value bits r1 to r10 of the random binary code RBC.

Each of the plurality of first adders HA11 to HA12 may perform an adding (summing) operation on a respective output of the plurality of second AND gates 621 to 630 and a respective output of the plurality of first AND gates 611 to 620, and may provide a carry to an adder adjacent to the first direction DR1 when the carry is generated.

Each of the plurality of second adders HA2 to FA29 may perform an adding (summing) operation on a respective output of the plurality of third AND gates 631640 and a respective output of the plurality of first adders HA11 to HA12, and may provide a carry to an adder adjacent to the first direction DR1 when the carry is generated.

Each of the plurality of third adders FA3 to FA39 may perform an adding (summing) operation on a respective output of the plurality of second adders HA2 to FA29 and a respective output of the plurality of fourth AND gates 641 to 650, and may provide a carry to an adder adjacent to the first direction DR1 when the carry is generated.

The output of the first AND gate 611 may be provided as a first output bit v1, the output of the first adder HA11 may be provided as a second output bit v2, the output of the eleventh adder HA2 may be provided as a third output bit v3, each output of the plurality of third adders FA3 to FA39 may be provided as a respective one of output bits (e.g., a fourth output bit v4, a fifth output bit v5, a sixth output bit v6, a seventh output bit v7, an eighth output bit v8, a ninth output bit v9, a tenth output bit v10, an eleventh output bit v11, a twelfth output bit v12, and a thirteenth output bit v13), and a carry bit of the adder FA39 may be provided as a fourteenth output bit v14.

Consequently, when the multiplier circuit performs a multiplication operation on the counted value CV and the entire plurality of bits r1 to r10 of the random binary code RBC, a circuit complexity of the multiplier circuit may be increased.

However, in the multiplier circuit 600, according to example embodiments, because hatched adders (e.g., the first adder HA11, the second adder FA11, the third adder FA12, the fourth adder FA13, the eleventh adder HA2, the twelfth adder FA21, the thirteenth adder FA22, the fourteenth adder FA23, the twenty-first adder FA3, the twenty-second adder FA31, the twenty-third adder FA32, and the twenty-fourth adder FA33, hereinafter generally referred to as 671) are associated with generating the lower bit LB, the hatched adders 671 may not be included in multiplier circuit 600 or may be deactivated in the multiplication operation. In addition, because hatched adders (e.g., the tenth adder HA12, the nineteenth adder FA28, the twentieth adder FA29, the twenty-eighth adder FA37, the twenty-ninth adder FA38, and the thirtieth adder FA39, hereinafter generally referred to as 673) are associated with second upper bits (e.g., the eighth random value bit r8, the ninth random value bit r9, and the tenth random value bit r10) for generating the excess bit EXB, the hatched adders 673 may not be included in multiplier circuit 600 and/or may be deactivated in the multiplication operation. Accordingly, a circuit complexity of the multiplier circuit 600 may be reduced, when compared to a related multiplier circuit.

That is, the multiplier circuit 600 may generate the sub multiplied value SMV including the eighth to tenth output bits v8 to v10 by including and/or activating the fifth adder FA14, the sixth adder FA15, the seventh adder FA16, the eighth adder FA17, the ninth adder FA18, the fifteenth adder FA24, the sixteenth adder FA25, the seventeenth adder FA26, the eighteenth adder FA27, the twenty-fifth adder FA34, the twenty-sixth adder FA35, and the twenty-seventh adder FA36, which are associated with multiplication operation on first upper bits (e.g., the fifth to tenth random value bits r5 to r10) and the counted value CV, the excess bit generator 660 may generate the excess bit EXB by performing an operation based on second upper bits (e.g., the eighth to tenth random value bits r8 to r10) associated with generating excess values (e.g., the eleventh to fourteenth output bits v11 to v14), third upper bits (e.g., the second to fourth counted value bits c2 to c4) of the counted value CV, and carry bits (e.g., a first carry bit cr1, a second carry bit cr2, and a third carry bit cr3), and the multiplier circuit 600 may provide the comparison circuit 530 in FIG. 6 with the multiplied value MV including the sub multiplied value SMV and the excess bit EXB. The adder FA18 may generate the first carry bit cr1, the adder FA27 may generate the second carry bit cr2, and the adder FA36 may generate the third carry bit cr3.

Therefore, when a result of an operation on the second upper bits (e.g., the eighth to tenth random value bits r8 to r10), the third upper bits (e.g., the second to fourth counted value bits c2 to c4), and the first to third carry bits cr1 to cr3 has a first logic level, the excess bit EXB may have a first logic level. When the result of an operation on the second upper bits (e.g., the eighth to tenth random value bits r8 to r10), the third upper bits (e.g., the second to fourth counted value bits c2 to c4), and the first to third carry bits cr1 to cr3 has a first logic level, there is a high probability that the multiplied value MV is greater than the reference value THV.

The comparison circuit 530 may compare the multiplied value MV including the sub multiplied value SMV and the excess bit EXB with the reference value THV and may determine a logic level of the updating signal UD.

As mentioned above, the reference value THV may correspond to a maximum value of the random binary code RBC. When the random binary code RBC includes M bits, the reference value THV may correspond to 2^{M}−1, where M is a positive integer greater than three (3) (e.g., M>3).

When the excess bit EXB has a first logic level and the sub multiplied value SMV has a non-zero value, the comparison circuit 530 may determine that the multiplied value MV is greater than the reference value THV, and may output the updating signal UD with a second logic level at the first time point.

When the excess bit EXB has a first logic level and the sub multiplied value SMV has a zero value, the comparison circuit 530 may determine that the multiplied value MV is less than or equal to the reference value THV, and may output the updating signal UD with a first logic level at the first time point.

When the excess bit EXB has a second logic level, the comparison circuit 530 may determine that the multiplied value MV is less than or equal to the reference value THV, and may output the updating signal UD with a first logic level at the first time point.

FIG. 9B is a circuit diagram illustrating an example of the excess bit generator in the multiplier circuit of FIG. 9A, according to example embodiments.

Referring to FIG. 9A, the excess bit generator 660 may include a plurality of AND gates (e.g., a first AND gate 661, a second AND gate 662, and a third AND gate 663), and a plurality of OR gates (e.g., a first OR gate 664, a second OR gate 665, and a third OR gate 666).

The first AND gate 661 may perform an AND operation on the tenth random value bit r10 and the second counted value bit c2. The first OR gate 664 may perform an OR operation on the ninth and tenth random value bits r9 and r10. The second OR gate 665 may perform an OR operation on the second upper bits (e.g., the eighth to tenth random value bits r8 to r10).

The second AND gate 662 may perform an AND operation on an output of the first OR gate 664 and the third counted value bit c3. The third AND gate 663 may perform an AND operation on an output of the second OR gate 665 and the fourth counted value bit c4. The third OR gate 666 may perform an OR operation on the outputs of the first to third AND gates 661 to 663 and the first to third carry bits cr1 to cr3, and may generate the excess bit EXB.

Therefore, when at least one of the first to third carry bits cr1 to cr3 has a first logic level, when both the tenth random value bit r10 and the second counted value bit c2 have a first logic level, when at least one of the ninth random value bit r9 or the tenth random value r10 has a first logic level and the third counted value bit c3 has a first logic level, or when at least one of the second upper bits (e.g., the eighth to tenth random value bits r8 to r10) has a first logic level and the fourth counted value bit c4 has a first logic level, the excess bit EXB may have a first logic level.

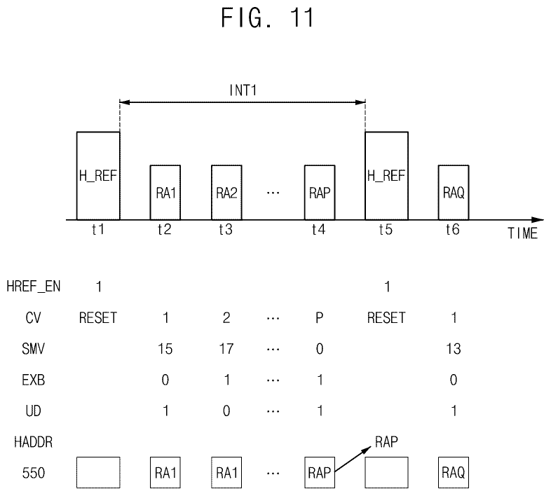

FIG. 10 is a timing diagram of a hammer refresh performed by the semiconductor memory device, according to example embodiments.

Referring to FIG. 10, the semiconductor memory device 200 may perform a hammer refresh (operation) H_REF at first time point t1 and at fifth time point t5. The hammer refresh H_REF may correspond to TRR. The semiconductor memory device 200 may perform the hammer refresh H_REF periodically. For example, the semiconductor memory device 200 may perform the hammer refresh H_REF at a periodic time interval INT1.

After the semiconductor memory device 200 performs the hammer refresh H_REF at the time point t1, the semiconductor memory device 200 may receive an active command and an access row address corresponding the active command. For example, the semiconductor memory device 200 may receive first to P-th active commands and first to P-th row addresses (e.g., a first row address RA1, a second row address RA2, to a P-th row address RAP) at second to fourth time points t2 to t4, respectively. Here, P is a positive integer greater than one (1).

The semiconductor memory device 200 may determine a row address (e.g., a hammer address) to be a target of the hammer refresh H_REF at the time point t5. For example, the semiconductor memory device 200 may determine one of the first to P-th row addresses RA1 to RAP as the hammer address. The semiconductor memory device 200 may determine one or more victim row addresses based on the hammer address. The semiconductor memory device 200 may determine a row address of at least one memory cell row adjacent to the hammer address as the victim row addresses.

In example embodiments, the semiconductor memory device 200 may determine the hammer address when receiving the active command. The semiconductor memory device 200 may determine the hammer address at respective one of the second to fourth time points t2 to t4. The semiconductor memory device 200 may determine a row address that may be received after the hammer refresh H_REF as the hammer address. The semiconductor memory device 200 may determine the first row address RA1 received at the time point t2 as the hammer address. The semiconductor memory device 200 may determine one of the first and second row addresses RA1 and RA2 as the hammer address at the time point t3. The semiconductor memory device 200 may determine whether to update the hammer address with the second row address RA2 at the time point t3. The semiconductor memory device 200 may determine whether to update the hammer address with the P-th row address RAP at the fourth time point t4.

At respective one of the second to fourth time points t2 to t4, the semiconductor memory device 200 may generate the random binary code RBC and the counted value CV, and may generate a multiplied value by performing multiplication operation based on the first bits of the random binary code RBC and the counted value CV. At respective one of the second to fourth time points t2 to t4, the semiconductor memory device 200 may compare the multiplied value with the reference value and may determine a hammer address based on a result of the comparison. The semiconductor memory device 200 may determine a maximum value of the random binary code RBC and the reference value.

At the time point t5, the semiconductor memory device 200 may determine the victim row addresses based on the hammer address. The semiconductor memory device 200 may perform the hammer refresh H_REF based on the victim row addresses.

After the semiconductor memory device 200 performs the hammer refresh H_REF at the time point t5, the semiconductor memory device 200 may receive a Q-th active command and a Q-th row address RAQ corresponding to the Q-th active command. Here, Q may be a positive integer greater than P. The semiconductor memory device 200 may determine the Q-th row address RAQ at the time point t6 as an aggressor row address.

After the semiconductor memory device 200 outputs the aggressor row address, the semiconductor memory device 200 may reset the hammer address register 550.

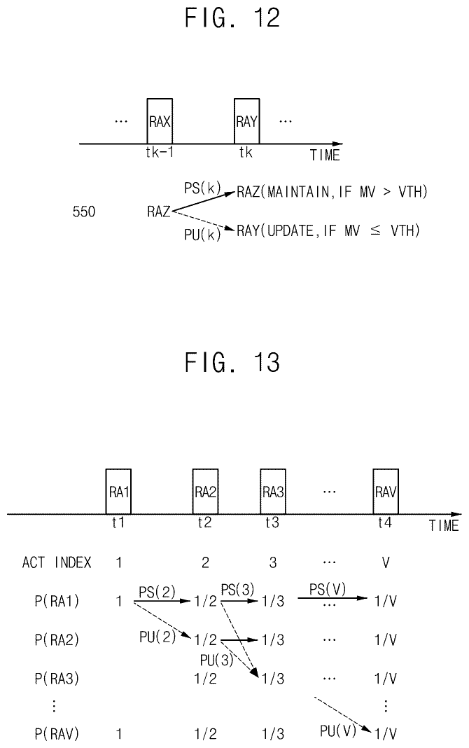

FIG. 11 is a timing diagram of the semiconductor memory device determining a hammer address, according to example embodiments.

Referring to FIG. 11, the semiconductor memory device 200 may perform hammer refresh H_REF at the first and fifth time points t1 and t5. The hammer refresh H_REF may correspond to TRR. The semiconductor memory device 200 may perform the hammer refresh H_REF periodically. For example, the semiconductor memory device 200 may perform the hammer refresh H_REF at a periodic time interval INT1.

In example embodiment, the semiconductor memory device 200 may generate a hammer refresh enable signal HREF_EN at a periodic time interval INT1 and may perform the hammer refresh H_REF based on the hammer refresh enable signal HREF_EN. The semiconductor memory device 200 may generate a hammer refresh enable signal HREF_EN based on a command received from the memory controller 30. For example, the memory controller 30 may apply a refresh command or a refresh management command to the semiconductor memory device 200 at the first time point t1 and the semiconductor memory device 200 may generate the hammer refresh enable signal HREF_EN with the period of the time interval INT1 from the first time point t1. The semiconductor memory device 200 may generate the hammer refresh H_REF based on the hammer refresh enable signal HREF_EN having a logic high level.

The counter 510 may operate based on the hammer refresh enable signal HREF_EN. The counter 510 may generate the counted value CV by counting the active signals IACT corresponding to the active commands. For example, the counter 510 may set the counted value CV to one (1) based on the active command at the time point t1. The counter 510 may increase the counted value CV at the third to fourth time points t3 to t4 whenever the counter 510 receives the active signal IACT. The counter 510 may reset and/or initialize the counted value CV based on the hammer refresh enable signal HREF_EN having a logic high level.

The random code generator 520 may generate the random binary code RBC based on the clock signal CLK.

The random code generator 520 may generate fifteen (15) in response to receiving the clock signal CLK at the time point t2, may generate three (3) in response to receiving the clock signal CLK at the time point t3, and may generate five (5) in response to receiving the clock signal CLK at the fourth time point t4. However, the present disclosure is not limited in this regard, and the random code generator 520 may generate other values in response to receiving the clock signal CLK.

As mentioned above, the random code generator 520 may be implemented with a linear feedback shift register.

The multiplier circuit 600 may generate the sub multiplied value SMV by performing the multiplication operation on the counted value CV and the first upper bits of the random binary code RBC, may generate the excess bit EXB by performing operation on second upper bits of the first upper bits and third upper bits of the counted value CV and may provide the comparison circuit 530 with the multiplied value MV including the sub multiplied value SMV and the excess bit EXB.

For example, the multiplier circuit 600 may generate the sub multiplied value SMV of fifteen (15) and the excess bit EXB of zero (0) at the time point t2, may generate the sub multiplied value SMV of seventeen (17) and the excess bit EXB of one (1) at the time point t3, and may generate the sub multiplied value SMV of zero (0) and the excess bit EXB of one (1) at the fourth time point t4.

The comparison circuit 530 may compare the sub multiplied value SMV of fifteen (15) and the excess bit EXB of zero (0) with the reference value THV at the time point t2, may determine the multiplied value MV is equal to or smaller than the reference value VTH because the excess bit EXB has a second logic level, and may provide the hammer address register 550 with the updating signal UD having a first logic level. The hammer address register 550 may store the row address RA1 at the second time point t2 therein based on the updating signal UD having a first logic level.

The comparison circuit 530 may compare the sub multiplied value SMV of seventeen (17) and the excess bit EXB of one (1) with the reference value THV at the third time point t3, may determine the multiplied value MV is greater than the reference value VTH because the excess bit EXB has a first logic level and the sub multiplied value SMV has a non-zero value, and may provide the hammer address register 550 with the updating signal UD having a second logic level. The hammer address register 550 may maintain the row address RA1 at the third time point t3 based on the updating signal UD having a first logic level.

The comparison circuit 530 may compare the sub multiplied value SMV of zero (0) and the excess bit EXB of one (1) with the reference value THV at the third time point t3, may determine the multiplied value MV is less than or equal to the reference value VTH because the excess bit EXB has a first logic level and the sub multiplied value SMV has a zero value, and may provide the hammer address register 550 with the updating signal UD having a first logic level. The hammer address register 550 may store the row address RAP at the fourth time point t4 based on the updating signal UD having a first logic level.

When the hammer refresh enable signal HREF_EN transitions to a first logic level at the fifth time point t5, the hammer address register 550 may output the row address RAP stored therein as the hammer address HADDR and the counter 510 and the hammer address register 550 may be reset.

The comparison circuit 530 may compare the sub multiplied value SMV of thirteen (13) and the excess bit EXB of zero (0) with the reference value THV at the sixth time point t6, may determine the multiplied value MV is less than or equal to the reference value VTH because the excess bit EXB has a second logic level, and may provide the hammer address register 550 with the updating signal UD having a first logic level. The hammer address register 550 may store the row address RAQ at the sixth time point t6 based on the updating signal UD having a first logic level.

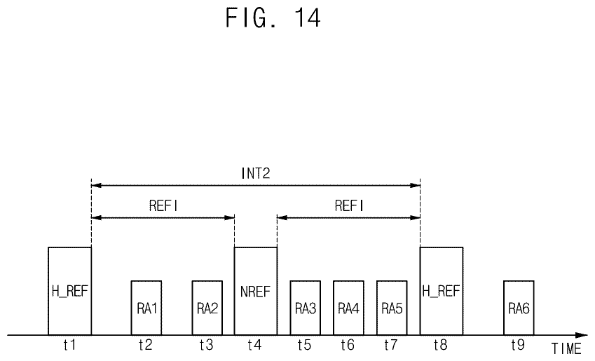

FIG. 12 is a diagram of an operation of the hammer address register, according to example embodiments.

Referring to FIG. 12, the hammer address register 550 may receive a row address RAX at a (k−1)-th time point tk−1, where k is a positive integer greater than one (1). The hammer address register 550 may store the row address RAX based on a logic level of the updating signal UD at the (k−1)-th time point tk−1.

The hammer address register 550 may receive a row address RAY at a k-th time point tk. When the multiplied value MV is greater than the reference value THV, the hammer address register 550 may receive the updating signal UD having a second logic level and maintain the row address RAX stored therein. When the multiplied value MV is equal to or smaller than the reference value THV, the hammer address register 550 may receive the updating signal UD having a first logic level and update the row address RAX stored therein with the row address RAY.

The hammer address register 550 may maintain the row address RAX with a probability of PS(k). The probability of PS(k) may be associated with a number of active commands received from a time point of a just previous hammer refresh to the k-th time point tk. For example, when k active commands are received from the time point of the just previous hammer refresh to the k-th time point tk, the probability of PS(k) may be expressed as 1−(1/k).

The hammer address register 550 may change the row address with a probability of PU(k). The probability of PU(k) may be associated with a number of active commands received from a time point of a just previous hammer refresh to the time point k-th tk. For example, when k active signals are received from the time point of the just previous hammer refresh to the k-th time point tk, the probability of PU(k) may be expressed as 1/k.

A sum of the probability of PS(k) and the probability of PU(k) may be one (1). The hammer address register 550 may maintain or change the row address RAY at the tk-th time point tk.

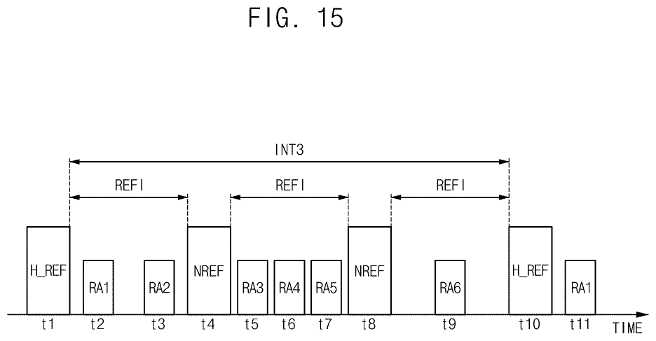

FIG. 13 is a diagram of an operation of the hammer address register, according to example embodiments.

Referring to FIG. 13, the semiconductor memory device 200 may receive active commands and row addresses (e.g., a first row address RA1, the second row address RA2, a third row address RA3, to a V-th row address RAV, where V is a positive integer greater than three (3)) corresponding to the active commands at first to fourth time points t1 to t4, respectively. Each of the active commands may be identified by an index ACT INDEX. The semiconductor memory device 200 may receive an initial active command at the first time point t1.

The semiconductor memory device 200 may include the hammer address register 550 that may determine one of the first to V-th row addresses RA1 to RAV as a hammer address at the first to fourth time points t1 to t4 and stores the hammer address therein. The hammer address register 550 may store one row address. Hereinafter, description on an operation that the semiconductor memory device 200 that determines the hammer address and stores the hammer address may be based on a trellis analysis scheme.

The semiconductor memory device 200 may receive the first row address RA1 at the first time point t1. The semiconductor memory device 200 may determine the first row address RA1 received at the first time point t1 as the hammer address. The semiconductor memory device 200 may receive the second row address RA2 at the second time point t2. The semiconductor memory device 200 may maintain the hammer address with first row address RA1 with a probability of PS(2) at the second time point t2. The semiconductor memory device 200 may change the hammer address with second row address RA2 with a probability of PU(2) at the second time point t2. Each of the probability of PS(2) and the probability of PU(2) may be 1/2 at the second time point t2. That is, at the second time point t2, the hammer address may be the row address RA1 with a probability P(RA1) of ½ and may be the first row address RA1 with a probability P(RA2) of ½.

The semiconductor memory device 200 may receive the third row address RA3 at the third time point t3. The semiconductor memory device 200 may maintain the previous hammer address (e.g., the first row address RA1 or the second row address RA2) with a probability of PS(3) at the third time point t3. The semiconductor memory device 200 may change the hammer address with the third row address RA3 with a probability of PU(3) at the third time point t3. The probability of PS(3) may be ⅔ and the probability of PU(3) may be ⅓ at the third time point t3. That is, at the third time point t3, the hammer address may be the first row address RA1 with a probability P(RA1) of ⅓ (e.g., corresponding to PS(2)×PS(3)), may be the second row address RA2 with a probability P(RA2) of ⅓ (e.g., corresponding to PU(2)×PS(3)) and may be the third row address RA3 with a probability P(RA3) of ⅓ (e.g., corresponding to PS(2)×PU(3)+PU(2)×PU(3)).

The semiconductor memory device 200 may receive the V-th row address RAV at the fourth time point t4. The semiconductor memory device 200 may maintain previous the hammer address with a probability of PS(V) at the fourth time point t4. The semiconductor memory device 200 may change the hammer address with V-th row address RAV with a probability of PU(V) at the fourth time point t4. At the fourth time point t4, the hammer address may be the first row address RA1 with a probability P(RA1) of 1/V, may be the second row address RA2 with a probability P(RA2) of 1/V, may be the third row address RA3 with a probability P(RA3) of 1/V, or may be the third row address RA3 with a probability P(RAV) of 1/V.

When the first to V-th row addresses RA1 to RAV are different, the semiconductor memory device 200 may determine each of the first to V-th row addresses RA1 to RAV as the hammer address at each of the first to fourth time points t1 to t4 with a same probability. When at least two of the first to V-th row addresses RA1 to RAV are the same with respect to each other, the semiconductor memory device 200 may determine the same row address as the hammer address with a relatively high probability. For example, when the first row address RA1 and the third row address RA3 are the same, the semiconductor memory device 200 may determine the first row address RA1 as the hammer address with a probability of 2/V.

Even though the semiconductor memory device 200 receives one row address, the semiconductor memory device 200 may perform the hammer refresh by determining the received row address as the hammer address. The semiconductor memory device 200 may provide a strong defense against various attack patterns by selecting one of received row address as the hammer address with substantially the same probability.

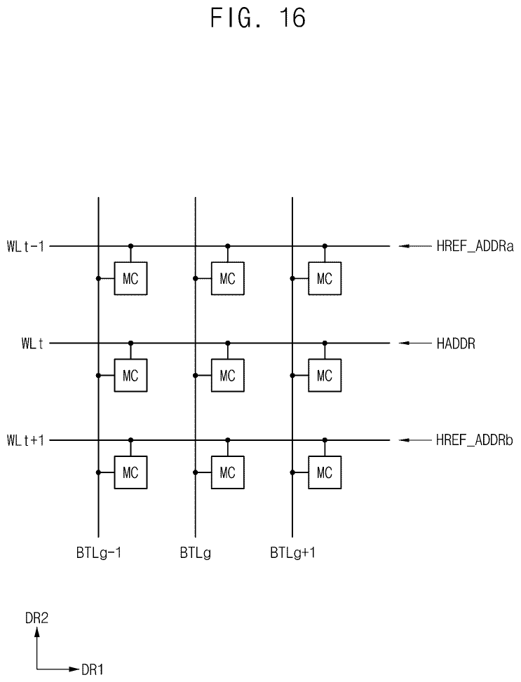

FIG. 14 is a timing diagram of a refresh operation performed by the semiconductor memory device, according to example embodiments.

Referring to FIG. 14, the semiconductor memory device 200 may perform a hammer refresh H_REF at first and eighth time points t1 and t8, and/or may perform a normal refresh (operation) NREF at a fourth time point t4. The hammer refresh H_REF may correspond to TRR. The semiconductor memory device 200 may perform the hammer refresh H_REF and the normal refresh NREF periodically.

In example embodiments, the semiconductor memory device 200 may determine a ratio of the hammer refresh H_REF and the normal refresh NREF. For example, the semiconductor memory device 200 may determine a refresh ratio between the hammer refresh H_REF and the normal refresh NREF to be 1:1. The semiconductor memory device 200 may perform the hammer refresh H_REF and the normal refresh NREF with a period of a time interval REFI. The time interval REFI may correspond to a maximum average refresh internal tREFI as disclosed in standards of the Joint Electron Device Engineering Council (JEDEC). The semiconductor memory device 200 may perform the hammer refresh H_REF with a period of a time interval INT2. The time interval INT2 may be determined based on the time interval REFI and the refresh ratio. For example, when a refresh ratio between the hammer refresh H_REF and the normal refresh NREF is 1:a, the time interval INT2 may be greater than a time interval corresponding to REFI×(a+1). As shown in FIG. 14, the time interval INT2 may be greater than REFI×2. However, the present disclosure is not limited in this regard, and the time interval INT2 may be set to other values.

After the semiconductor memory device 200 performs the hammer refresh H_REF at the first time point t1, the semiconductor memory device 200 may receive an active command and an access row address corresponding the active command. For example, the semiconductor memory device 200 may receive active commands and first and second row addresses RA1 and RA2 at the second and third time points t2 and t3, respectively.

The semiconductor memory device 200 may perform the normal refresh NREF at the fourth time point t4. The semiconductor memory device 200 may perform the normal refresh NREF based on the counter refresh address CREF_ADDR generated by the normal refresh circuit 420 in FIG. 5. In example embodiments, the semiconductor memory device 200 may determine a number of memory cell rows to be targets of the normal refresh based on the refresh ratio.

After the semiconductor memory device 200 performs the normal refresh NREF at the fourth time point t4, the semiconductor memory device 200 may receive an active command and an access row address corresponding the active command. For example, the semiconductor memory device 200 may receive active commands and third to fifth row addresses RA3 to RA5 at the fifth to seventh time points t5 to t7, respectively.

The semiconductor memory device 200 may determine a row address (e.g., a victim row address) to be a target of the hammer refresh H_REF at the eighth time point t8. The semiconductor memory device 200 may determine one of the first to fifth row addresses RA1 to RA5 received from a time point of a just previous hammer refresh H_REF to a time point of current hammer refresh H_REF (e.g., during the time interval INT2) as the hammer address. The semiconductor memory device 200 may determine one or more victim row addresses based on the hammer address. The semiconductor memory device 200 may determine a row address of at least one memory cell row adjacent to the hammer address as the victim row addresses.

In example embodiments, the semiconductor memory device 200 may determine the hammer address when receiving the active command. The semiconductor memory device 200 may determine the hammer address at respective one of the second to seventh time points t2 to t7. The semiconductor memory device 200 may determine a row address that is received after the hammer refresh H_REF as the hammer address. The semiconductor memory device 200 may determine the first row address RA1 received at the second time point t2 as the hammer address. The semiconductor memory device 200 may determine one of the first and second row addresses RA1 and RA2 as the hammer address at the third time point t3. The semiconductor memory device 200 may determine whether to update the hammer address with the second row address RA2 at the third time point t3. The semiconductor memory device 200 may determine whether to update the hammer address with each of the third to fifth row addresses RA3 to RA5 at each of the fifth to seventh time points t5 to t7.

At respective one of the second to seventh time points t2 to t7, the semiconductor memory device 200 may generate the random binary code RBC and the counted value CV, and may generate a multiplied value by performing multiplication operation based on the first bits of the random binary code RBC and the counted value CV. At respective one of the second to seventh time points t2 to t7, the semiconductor memory device 200 may compare the multiplied value with the reference value and may determine whether to update the hammer address with each of the first to fifth row addresses RA1 to RA5 based on a result of the comparison.

After the semiconductor memory device 200 performs the hammer refresh H_REF at the eighth time point t8, the semiconductor memory device 200 may receive an active command and a sixth row address RA6 corresponding to the active command at a ninth time point t9. The semiconductor memory device 200 may determine the sixth row address RA6 at the ninth time point t9 as the hammer address.

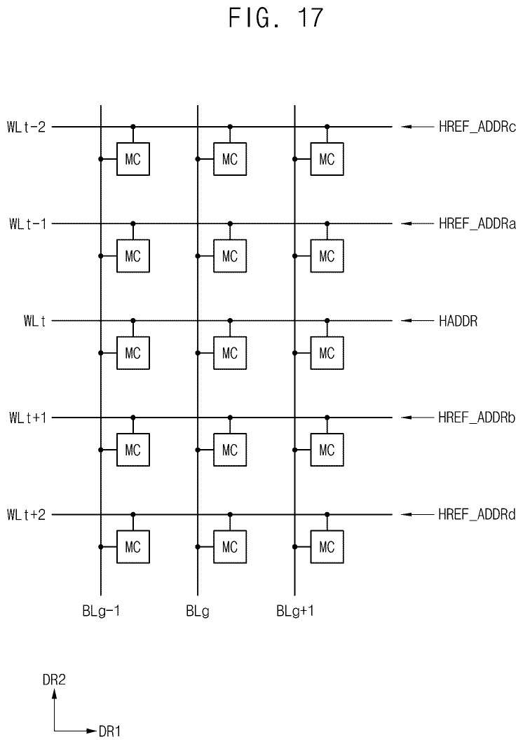

FIG. 15 is a timing diagram of a refresh operation performed by the semiconductor memory device, according to example embodiments. The timing diagram of FIG. 15 may be similar in many respects to the timing diagram described above with reference to FIG. 14, and may include additional features not mentioned above. Some of the elements or descriptions of the timing diagram described above with reference to FIG. 14 have been omitted for the sake of brevity.

Referring to FIG. 15, the semiconductor memory device 200 may perform hammer refresh H_REF at first and tenth time points t1 and t10 and may perform a normal refresh (operation) NREF at the fourth time point t4. The hammer refresh H_REF may correspond to TRR. The semiconductor memory device 200 may perform the hammer refresh H_REF and the normal refresh NREF periodically.

In example embodiments, the semiconductor memory device 200 may determine a ratio of the hammer refresh H_REF and the normal refresh NREF. For example, the semiconductor memory device 200 may determine a refresh ratio between the hammer refresh H_REF and the normal refresh NREF to be 1:2. The semiconductor memory device 200 may perform the hammer refresh H_REF and the normal refresh NREF with a period of a time interval REFI. The time interval REFI may correspond to a maximum average refresh internal tREFI as disclosed in standards of JEDEC. The semiconductor memory device 200 may perform the hammer refresh H_REF with a period of a time interval INT3. The time interval INT3 may be determined based on the time interval REFI and the refresh ratio.

After the semiconductor memory device 200 performs the normal refresh NREF at the fourth and eighth time points t4 and t8, the semiconductor memory device 200 may receive active commands and row addresses corresponding the active commands. For example, the semiconductor memory device 200 may receive active commands and third to sixth row addresses RA3 to RA6 at the fifth to seventh and ninth time points t5 to t7 and t9, respectively.

The semiconductor memory device 200 may determine a row address (e.g., a victim row address) to be a target of the hammer refresh H_REF at the tenth time point t10. The semiconductor memory device 200 may determine one of the first to sixth row addresses RA1 to RA6 received from a time point of a previous hammer refresh H_REF to a time point of current hammer refresh H_REF (e.g., during the time interval INT3) as the hammer address. The semiconductor memory device 200 may determine one or more victim row addresses based on the hammer address. The semiconductor memory device 200 may determine a row address of at least one memory cell row adjacent to the hammer address as the victim row addresses.

The semiconductor memory device 200 may determine one or more victim row addresses based on the hammer address at time point t10. The semiconductor memory device 200 may perform the hammer refresh H_REF based on the one or more victim row addresses.

After the semiconductor memory device 200 performs the hammer refresh H_REF at the tenth time point t10, the semiconductor memory device 200 may receive an active command and a seventh row address RA7 corresponding to the active command at an eleventh time point t11. The semiconductor memory device 200 may determine the sixth row address RA6 at the eleventh time point t11 as the hammer address.

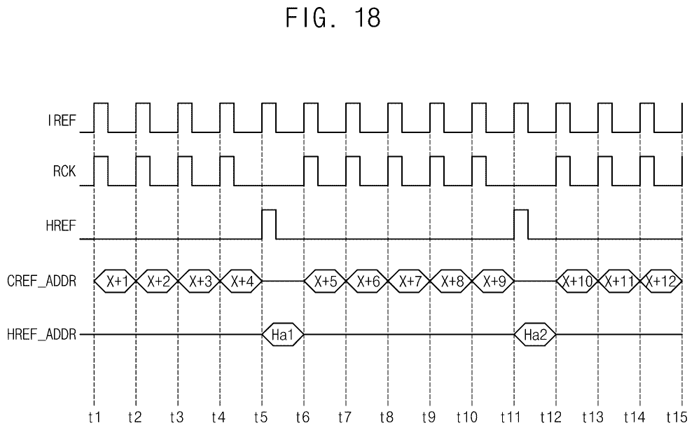

FIG. 16 is a diagram illustrating a portion of a memory cell array describing generation of hammer refresh addresses.

FIG. 16 illustrates a plurality of word lines (e.g., a (t−1)-th word line WLt−1, a t-th word line WLt, and a (t+1)-th WLt+1, where t is a positive integer greater than two (2)), a plurality of bit lines (e.g., a (g−1)-th bit line BLg−1, a g-th bit line BLg, and a (g+1)-th bit line BLg+1, where g is a positive integer greater than two (2)), and a plurality of memory cells MC coupled to the plurality of word lines and the plurality of bit lines in the memory cell array. The plurality of word lines WLt−1 to WLt+1 are extended in the first direction DR1 and arranged sequentially along the second direction DR2. The plurality of bit lines BLg−1 to BLg+1 are extended in the second direction DR2 and arranged sequentially along the first direction DR1. It is to be understood that the (t−1)-th and the t-th word lines WLt−1 and WLt may be physically directly adjacent to each other since there may be no intervening word lines between the (t−1)-th and the t-th word lines WLt−1 and WLt.

For example, the middle word lines (e.g., the t-th word line WLt) may correspond to the hammer address HADDR that has been intensively accessed. As used herein, an intensively-accessed word line may refer to a word line that has a relatively high activation number and/or has a relatively high activation frequency. Whenever the hammer word line (e.g., the middle word line WLt) is accessed, the hammer word line WLt may be enabled and precharged, and the voltage level of the hammer word line WLt may be increased and/or decreased. Word line coupling may cause the voltage levels of the adjacent (t−1)-th and (t+1)-th word lines WLt−1 and WLt+1 to fluctuate as the voltage level of the hammer word line WLt varies, and thus, the cell charges of the memory cells MC coupled to the adjacent (t−1)-th and (t+1)-th word lines WLt−1 and WLt+1 may be affected. As the hammer word line WLt may be accessed more frequently, the cell charges of the memory cells MC coupled to the adjacent (t−1)-th and (t+1)-th word lines WLt−1 and WLt+1 may be lost more rapidly, when compared to other memory cells.

The hammer refresh circuit 500 in FIG. 6 may provide the hammer refresh address HREF_ADDR representing the addresses HREF_ADDRa and HREF_ADDRb of the rows (e.g., the (t−1)-th and (t+1)-th word lines WLt−1 and WLt+1) that may be physically adjacent to the row of the hammer address HADDR (e.g., the hammer word line WLt), and an refresh operation for the adjacent (t−1)-th and (t+1)-th word lines WLt−1 and WLt+1 may be performed additionally based on (e.g., in response to) the hammer refresh address HREF_ADDR to reduce and/or possibly prevent the loss of data stored in the memory cells MC.

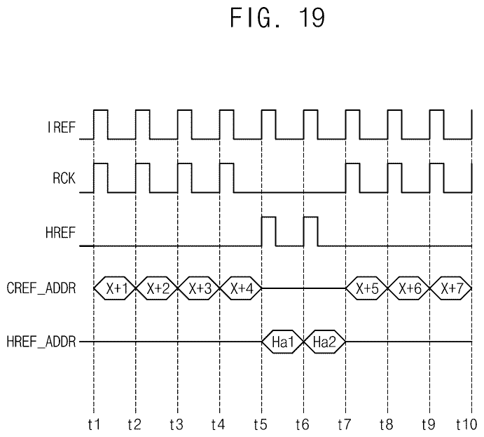

FIG. 17 is a diagram illustrating a portion of a memory cell array during generation of hammer refresh addresses.

FIG. 17 illustrates a plurality of word lines (e.g., a (t−2)-th word line WLt−2, a (t−1)-th word line WLt−1, a t-th word line WLt, a (t+1)-th word line WLt+1, and a (t+2)-th word line WLt+2, where t is a positive integer greater than two (2)), a plurality of bit lines (e.g., a (g−1)-th bit line BLg−1, a g-th bit line BLg, and a (g+1)-th bit line BLg+1, where g is a positive integer greater than two (2)), and a plurality of memory cells MC coupled to the plurality of word lines and the plurality of bit lines in the memory cell array. The plurality of word lines WLt−2 to WLt+2 are extended in the first direction DR1 and arranged sequentially along the second direction DR2.

The hammer refresh circuit 500 in FIG. 6 may provide the hammer refresh address HREF_ADDR representing addresses HREF_ADDRa, HREF_ADDRb, HREF_ADDRc and HREF_ADDRd of the rows (e.g., the (t−1)-th word line WLt−1, the (t+1)-th word line WLt+1, the (t−2)-th word line WLt−2, and the (t+2)-th word line WLt+2) that may be physically adjacent to the row of the hammer address HADDR (e.g., the middle (t-th) word line WLt), and an refresh operation for the adjacent word lines (e.g., the (t−1)-th word line WLt−1, the (t+1)-th word line WLt+1, the (t−2)-th word line WLt−2, and the (t+2)-th word line WLt+2) may be performed additionally based on (e.g., in response to) the hammer refresh address HREF_ADDR to reduce and/or possibly prevent the loss of data stored in the memory cells MC.

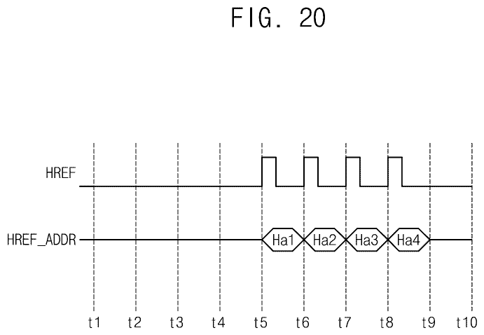

FIGS. 18, 19, and 20 are timing diagrams illustrating example operations of a refresh control circuit of FIG. 5, according to example embodiments.

FIGS. 18 and 19 illustrate generation of a refresh clock signal RCK, a hammer refresh signal HREF, a counter refresh address CREF_ADDR, and a hammer refresh address HREF_ADDR, with respect to the first refresh signal IREF1 that may be activated in a pulse shape at first to fifteenth activation time points t1 to t15 and/or at first to tenth activation time points t1 to t10. The intervals between the first to fifteenth activation time points t1 to t15 and/or the first to tenth activation time points t1-t10 of the refresh control signal IREF may be regular or irregular.

Referring to FIGS. 5 and 18, the refresh control logic 410 may activate the refresh clock signal RCK in synchronization with some time points (e.g., the first to fourth time points t1 to t4, the sixth to tenth time points t6 to t10, and the twelfth to fifteenth time points t12 to t15) from among the first to fifteenth activation time points t1-t15 of the first refresh signal IREF1, and may activate the hammer refresh signal HREF with the other time points (e.g., the fifth time point t5 and the eleventh time point t11).

The refresh counter 440 may generate the counter refresh address CREF_ADDR representing the sequentially changing addresses (e.g., a (X+1)-th address X+1 to a (X+12)-th address X+12, where X is a positive integer greater than zero (0)) in synchronization with the activation time points (e.g., the first to fourth time points t1 to t4, the sixth to tenth time points t6 to t10, and the twelfth to fourteenth time points t12 to t14) of the refresh clock signal RCK. The hammer refresh circuit 500 may generate the hammer refresh address HREF_ADDR representing the address Ha1 and Ha2 of the rows that are physically adjacent to the row of the hammer address in synchronization with the fifth and eleventh activation time points t5 and t11 of the hammer refresh signal HREF.

Referring to FIGS. 5 and 19, the refresh control logic 410 may activate the refresh clock signal RCK in synchronization with some time points (e.g., the first to fourth time points t1 to t4 and the seventh to tenth time points t7 to t10) from among the first to tenth activation time points t1 to t10 of the first refresh signal IREF1, and may activate the hammer refresh signal HREF with the other time points (e.g., the fifth time point t5 and the sixth time point t6).

The refresh counter 440 may generate the counter refresh address CREF_ADDR representing the sequentially changing addresses (e.g., the (X+1)-th to (X+7)-th addresses X+1 to X+7) in synchronization with the activation time points (e.g., the first to fourth time points t1 to t4 and the seventh to ninth time points t7 to t9) of the refresh clock signal RCK. The hammer refresh circuit 500 may generate the hammer refresh address HREF_ADDR representing the address Ha1 and Ha2 of the rows that are physically adjacent to the row of the hammer address in synchronization with the fifth and sixth activation time points t5 and t6 of the hammer refresh signal HREF.

Referring to FIGS. 5 and 20, the hammer refresh circuit 500 may generate the hammer refresh address HREF_ADDR representing the address Ha1, Ha2, Ha3 and Ha4 of the rows that are physically adjacent to the row of the hammer address in synchronization with the fifth to eighth activation time points t5 to t8 of the hammer refresh signal HREF.

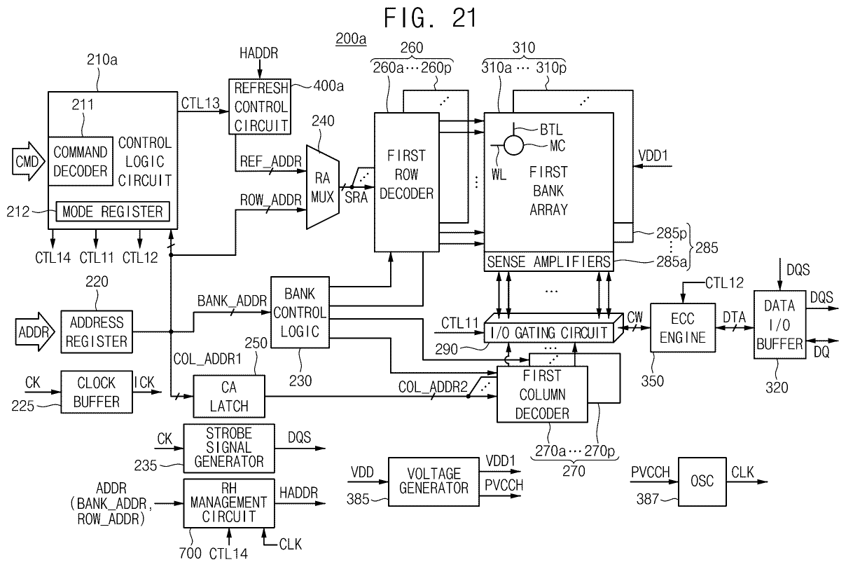

FIG. 21 is a block diagram illustrating an example of the semiconductor memory device in FIG. 1, according to example embodiments. The semiconductor memory device 200a of FIG. 21 may be similar in many respects to the semiconductor memory device 200 described above with reference to FIG. 1, and may include additional features not mentioned above. Some of the elements or descriptions of the semiconductor memory device 200a described above with reference to FIG. 1 have been omitted for the sake of brevity.

Referring to FIG. 21, a semiconductor memory device 200a may include a control logic circuit 210a, an address register 220, a bank control logic 230, a refresh control circuit 400a, a row address multiplexer 240, a column address latch 250, a row decoder 260, a column decoder 270, the memory cell array 310, a sense amplifier unit 285, a I/O gating circuit 290, an ECC engine 350, a clock buffer 225, a strobe signal generator 235, a voltage generator 385, an oscillator OSC 387, a row hammer (RH) management circuit 700, and a data I/O buffer 320.

The refresh control circuit 400a may sequentially increase and/or decrease the refresh row address REF_ADDR in a normal refresh mode in response to a third control signal CTL13 from the control logic circuit 210a. The refresh control circuit 400a may receive a hammer address HADDR in a hammer refresh mode, and may output hammer refresh addresses designating one or more victim memory cell rows physically adjacent to a memory cell row corresponding to the hammer address as the refresh row address REF_ADDR.

The row hammer management circuit 700 may receive the address ADDR (including the bank address BANK_ADDR and the row address ROW_ADDR) may generate a random binary code based on a clock signal CLK, may generate a multiplied value based on multiplication operation on a counted value and first upper bits corresponding to a portion of the random binary code, and may selectively store a first access row address corresponding to a first access command received at a first time point in a hammer address register therein based on comparing the multiplied value with a reference value. Therefore, the semiconductor memory device 200 may determine a hammer address (or may perform a hammer refresh operation) based on random pick with reducing circuit complexity of the row hammer management circuit 700.

The control logic circuit 210a may control operations of the semiconductor memory device 200a. For example, the control logic circuit 210a may generate control signals for the semiconductor memory device 200a in order to perform a write operation, a read operation, a normal refresh operation and a hammer refresh operation. The control logic circuit 210a may include a command decoder 211 that may decode the command CMD received from the memory controller 30 and a mode register 212 that may set an operation mode of the semiconductor memory device 200.

For example, the command decoder 211 may generate the control signals corresponding to the command CMD by decoding a write enable signal, a row address strobe signal, a column address strobe signal, a chip select signal, or the like. The control logic circuit 210 may generate a first control signal CTL1a to control the I/O gating circuit 290, the second control signal CTL12 to control the ECC engine 350, the third control signal CTL13 to control the refresh control circuit 400a, and a fourth control signal CTL14 to control the row hammer management circuit 700.

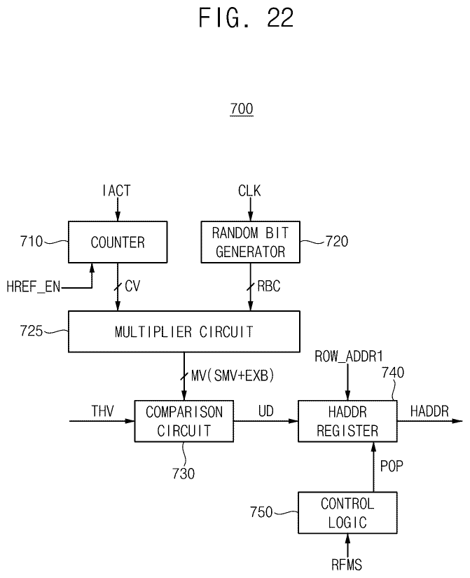

FIG. 22 is a block diagram illustrating an example of the row hammer management circuit in the semiconductor memory device of FIG. 21, according to example embodiments.

Referring to FIG. 22, the row hammer management circuit 700 may include a counter 710, a random bit generator 720, a multiplier circuit 725, a comparison circuit 730, a hammer address (HADDR) register 740, and a control logic 750.

The counter 710 may generate a counted value CV by counting the active signals IACT received until the first time point. The random bit generator 720 may generate a random binary code RBC based on the clock signal CLK.

In example embodiment, the random binary code RBC may include M bits and the counted value CV may include N bits. Here, M may be a positive integer greater than three (3) and N may be a positive integer less than M.

The multiplier circuit 725 may generate a multiplied value MV based on multiplication operation on the counted value CV and first upper bits corresponding to a portion of the random binary code RBC. The multiplied value MV may be referred to as an operated value. The multiplier circuit 725 may generate a sub multiplied value SMV by performing the multiplication operation on the counted value CV and the first upper bits of the random binary code RBC, may generate an excess bit EXB by performing operation on second upper bits corresponding to a portion of the first upper bits and third upper bits of the counted value CV and may provide the comparison circuit 730 with the sub multiplied value SMV and the excess bit EXB as the multiplied value MV.

The comparison circuit 730 may receive the multiplied value MV including the sub multiplied value SMV and the excess bit EXB, may compare the multiplied value MV with a reference value THV, may generate an updating signal UD based on a result of the comparison and may provide the updating signal UD to the hammer address register 740.

The hammer address register 740 may selectively store a first access row address ROW_ADDR1 received at the first time point, therein, based on a logic level of the updating signal UD.

The control logic 750 may provide a pop signal POP to the hammer address register 740 based on the refresh management signal RFMS and the hammer address register 740 may output, to the refresh control circuit 400a in FIG. 21, the hammer address HADDR stored therein based on the pop signal POP.

Because the multiplier circuit 725, instead of performing multiplication operation on entire bits of the random binary code RBC, generates the multiplied value MV including the sub multiplied value SMV and the excess bit EXB by performing multiplication operation on the counted value CV and the first upper bits corresponding to a portion of the random binary code RBC, circuit complexity of the multiplier circuit 725 may be reduced.

The multiplier circuit 725 may employ the multiplier circuit 600 of FIG. 9.

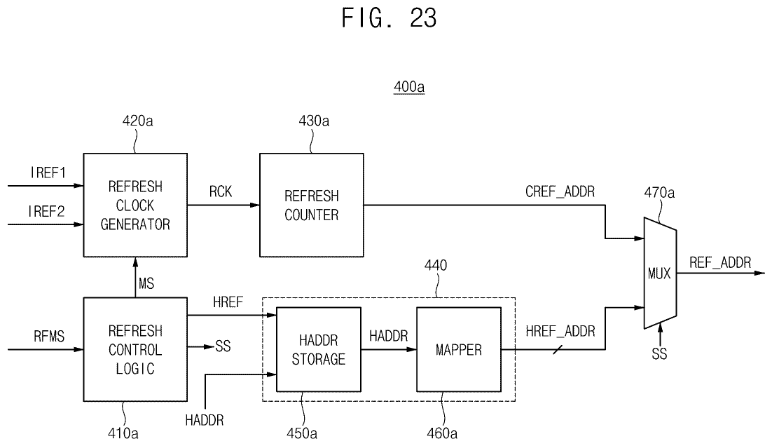

FIG. 23 is a block diagram illustrating an example of the refresh control circuit in FIG. 21, according to example embodiments.

Referring to FIG. 23, the refresh control circuit 400a may include a refresh control logic 410a, a refresh clock generator 420a, a refresh counter 430a, a hammer refresh address generator 440a, and a multiplexer 470a.

The refresh control logic 410a may provide a mode signal MS to the refresh clock generator 420a and may provide a selection signal SS to the multiplexer 470a, based on the refresh management signal RFMS. The refresh control logic 410 may receive a first refresh signal IREF1 and a second refresh signal IREF2. The refresh control logic 410 may provide the hammer refresh address generator 440a with a hammer refresh signal HREF to control output timing of the hammer address in response to one of the first refresh signal IREF1 and the second refresh signal IREF2.

The refresh clock generator 420a may generate a refresh clock signal RCK indicating a timing of a normal refresh operation based on the first refresh signal IREF1, the second refresh signal IREF2, and the mode signal MS. The refresh clock generator 420a may generate the refresh clock signal RCK in response to the receiving the first refresh signal IREF1 or during the second refresh signal IREF2 is activated.

When the command CMD from the memory controller 30 corresponds to an auto refresh command, the control logic circuit 210a in FIG. 21 may apply the first refresh signal IREF1 to the refresh control circuit 400a whenever the control logic circuit 210a receives the auto refresh command. When the command CMD from the memory controller 30 corresponds to a self-refresh entry command, the control logic circuit 210a may apply the second refresh signal IREF2 to the refresh control circuit 400a and the second refresh signal IREF2 is activated from a time point when the control logic circuit 210a receives the self-refresh entry command to a time point when control logic circuit 210a receives a self-refresh exit command.

The refresh counter 430a may generate a counter refresh address CREF_ADDR designating sequentially the memory cell rows by performing counting operation at the period of the refresh clock signal RCK, and may provide the counter refresh address CREF_ADDR to the multiplexer 470a.

The hammer refresh address generator 440a may include a hammer address storage 450a and a mapper 460a.

The hammer address storage 450a may store the hammer address HADDR and may output the hammer address HADDR to the mapper 460a in response to the hammer refresh signal HREF. The mapper 460a may generate hammer refresh addresses HREF_ADDR designating one or more victim memory cell rows physically adjacent to a memory cell row corresponding to the hammer address HADDR and may provide the hammer refresh addresses HREF_ADDR to the multiplexer 470a.

For example, the mapper 460a may generate the hammer refresh addresses HREF_ADDR designating addresses designating the one or more victim memory cell rows physically adjacent to a memory cell row corresponding to the hammer address HADDR.

In example embodiments, the hammer refresh address generator 440a may include the mapper 460a and may not include the hammer address storage 450a. In this case, the hammer address HADDR may be input to the mapper 460a from the row hammer management circuit 700 and the mapper 460a may output the hammer refresh addresses HREF_ADDR based on the hammer address HADDR.

The multiplexer 450 may output one of the counter refresh address CREF_ADDR and the hammer refresh addresses HREF_ADDR as the refresh row address REF_ADDR based on the selection signal SS.

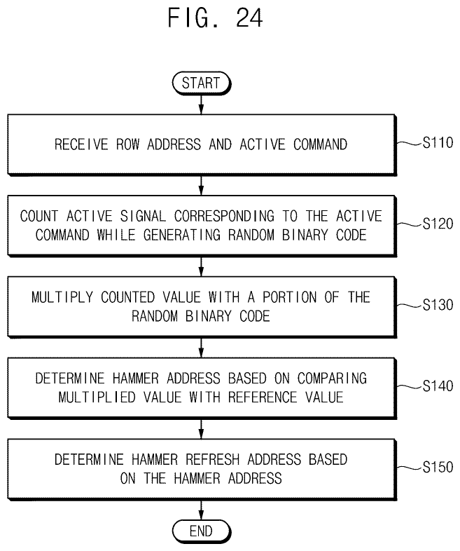

FIG. 24 is a flow chart illustrating a method of operating a semiconductor memory device, according to example embodiments.

Referring to FIGS. 3 to 20 and 24, in a method of operating a semiconductor memory device 200 including a memory cell array 310 which includes a plurality of memory cell rows and each of the memory cell rows includes a plurality of volatile memory cells, the semiconductor memory device 200 may receive an active command and a first access row address corresponding to the active command at a first time point (operation S110).

A hammer refresh circuit 500 in the semiconductor memory device 200 may generate a counted value CV by counting active signals corresponding active commands received until the first time point while generating a random binary code RBC based on a clock signal CLK (operation S120).

A multiplier circuit 600 in the hammer refresh circuit 500 may generate a multiplied value MV by generating a sub multiplied value SMV by performing a multiplication operation on the counted value CV and first upper bits of the random binary code RBC and by generating an excess bit EXB by performing operation on second upper bits of the first upper bits and third upper bits of the counted value CV and carries (operation S130).

A comparison circuit 530 in the hammer refresh circuit 500 may determine to store the first access address in the hammer address register 550 as a hammer address based on comparing the multiplied value CV with a reference value THV (operation S140).

A mapper 570 in the hammer refresh circuit 500 may determine a hammer refresh address based on the hammer address HADDR output from the hammer address register 550 (operation S150). That is, the mapper 570 may determine addresses of one or more victim memory cell rows which are physically adjacent to a memory cell row, corresponding to a hammer address output from the hammer address register 550 as the hammer refresh addresses.

Therefore, in the semiconductor memory device, according to example embodiments, the multiplier circuit may generate a multiplied value including a sub multiplied value and an excess bit based on multiplication operation on counted value and first upper bits corresponding to a portion of the random binary code, and may selectively store a first access row address corresponding to a first access command in the hammer address register based on comparing the multiplied value with a reference value. Therefore, the semiconductor memory device may determine a hammer address based on random pick while potentially reducing circuit complexity of the multiplier circuit, when compared to related multiplier circuits.

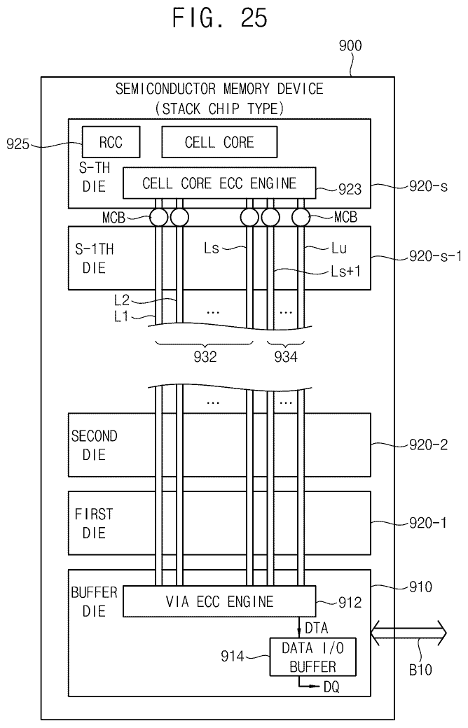

FIG. 25 is a block diagram illustrating a semiconductor memory device, according to example embodiments.

Referring to FIG. 25, a semiconductor memory device 900 may include at least one buffer die 910 and a plurality of memory dies 920 (e.g., a first memory die 920-1, a second memory die 920-2, to an (s−1)-th memory die 920-s−1, to an s-th memory die 920-s, where s is a positive integer greater than two (2)) providing a soft error analyzing and correcting function in a stacked chip structure.

The plurality of memory dies 920 may be stacked on the at least one buffer die 910 and may convey data through a plurality of through silicon via (TSV) lines.

Each of the plurality of memory dies 920 may include a cell core 921 to store data, a cell core ECC engine 923 that may generate transmission parity bits (e.g., transmission parity data) based on transmission data to be sent to the at least one buffer die 910, and a refresh control circuit (RCC) 925. The cell core 921 may include a plurality of memory cells having a DRAM cell structure.

The refresh control circuit 925 may employ the refresh control circuit 400 of FIG. 5. Therefore, the refresh control circuit 925 may include the hammer refresh circuit 500 of FIG. 6. Accordingly, the refresh control circuit 925 may receive a first active signal corresponding to a first active command received from the memory controller 30 at a first time point, may generate a counted value by counting active signals corresponding active commands received until the first time point, may generate a multiplied value based on multiplication operation on the counted value and first upper bits corresponding to a portion of a random binary code, may selectively store a first access row address corresponding to the first active command in a hammer address register therein based on comparing the multiplied value with a reference value and may perform a hammer refresh operation, at a refresh timing, on one or more victim memory cell rows which are physically adjacent to a memory cell row among the plurality of memory cell rows, corresponding to a hammer address output from the hammer address register. Therefore, the refresh control circuit 925 may determine a hammer address based on random pick while potentially reducing circuit complexity of the multiplier circuit, when compared to a related multiplier circuit.

The buffer die 910 may include a via ECC engine 912 that may correct a transmission error using the transmission parity bits when a transmission error is detected from the transmission data received through the TSV lines and may generate error-corrected data.

The buffer die 910 may further include a data I/O buffer 916. The data I/O buffer 916 may generate the data signal DQ by sampling the data DTA from the via ECC engine 912 and may output the data signal DQ to an outside.

The semiconductor memory device 900 may be and/or may include a stack chip type memory device and/or a stacked memory device that may convey data and/or control signals through the TSV lines. The TSV lines may be also referred to as through electrodes.

The cell core ECC engine 923 may perform error correction on data that may be outputted from a previous memory die (e.g., the (s−1)-th memory die 920-s−1 before the transmission data is sent.

A data TSV line group 932 that may be formed at one memory die (e.g., the (s−1)-th memory die 920-s−1) may include a plurality of data TSV lines (e.g., a first data TSV line L1, a second data TSV line L2, to an s-th data TSV line Ls, where s is a positive integer) , and a parity TSV line group 934 may include a plurality of parity TSV lines (e.g., a (s+1)-th parity TSV line Ls+1 to a u-th parity TSV line Lu, where u is a positive integer greater than s). The plurality of data TSV lines L1 to Ls of the data TSV line group 932 and the plurality of parity TSV lines L10 to Lu of the parity TSV line group 934 may be connected to micro bumps MCB that may be correspondingly formed among the plurality of memory dies 920.

The semiconductor memory device 900 may have a three-dimensional (3D) chip structure and/or a 2.5D chip structure to communicate with a host through a data bus B10. The buffer die 910 may be connected with the memory controller through the data bus B10.

According to example embodiments, as illustrated in FIG. 25, the cell core ECC engine 923 may be included in the s-th memory die 920-s, and the via ECC engine 912 may be included in the buffer die 910. Accordingly, it may be possible to detect and/or correct soft data fail. The soft data fail may include a transmission error that may be generated due to noise when data is transmitted through the TSV lines (e.g., the plurality of data TSV lines L1 to Ls).

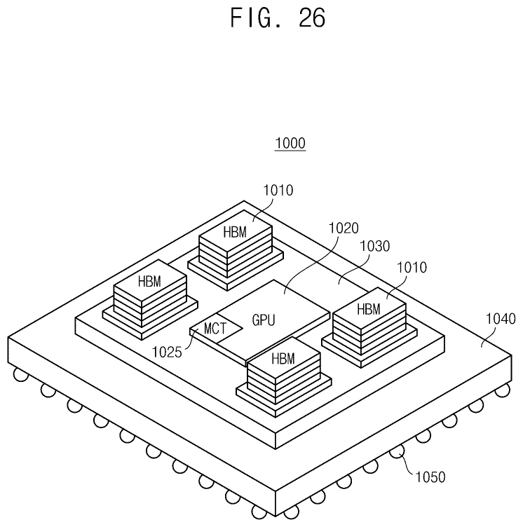

FIG. 26 is a configuration diagram illustrating a semiconductor package including the stacked memory device, according to example embodiments.

Referring to FIG. 31, a semiconductor package 1000 may include one or more stacked memory devices 1010 and a graphic processing unit (GPU) 1020.

The stacked memory devices 1010 and the GPU 1020 may be mounted on an interposer 1030, and the interposer on which the stacked memory device 1010 and the GPU 1020 are mounted, may be mounted on a package substrate 1040 mounted on solder balls 1050. The GPU 1020 may correspond to a semiconductor device which may perform a memory control function, and for example, the GPU 1020 may be implemented as an application processor (AP). The GPU 1020 may include a memory controller 1025 having a scheduler.

The stacked memory device 1010 may be implemented in various forms, and the stacked memory device 1010 may be and/or may include a memory device in a high bandwidth memory (HBM) form in which a plurality of layers are stacked. Accordingly, the stacked memory device 1010 may include a buffer die and a plurality of memory dies and each of the plurality of memory dies may include a refresh control circuit.

The plurality of stacked memory devices 1010 may be mounted on the interposer 1030, and the GPU 1020 may communicate with the plurality of stacked memory devices 1010. For example, each of the stacked memory devices 1010 and the GPU 1020 may include a physical region, and communication may be performed between the stacked memory devices 1010 and the GPU 1020 through the physical regions. When the stacked memory device 1010 includes a direct access region, a test signal may be provided into the stacked memory device 1010 through conductive means (e.g., solder balls 1050) mounted under package substrate 1040 and the direct access region.

Aspects of the present disclosure may be applied to systems using semiconductor memory devices that employ volatile memory cells. For example, aspects of the present disclosure may be applied to systems such as be a smart phone, a navigation system, a notebook computer, a desk top computer and a game console that use the semiconductor memory device as a working memory.

The foregoing is illustrative of example embodiments and is not to be construed as limiting thereof. Although a few example embodiments have been described, those skilled in the art may readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. A semiconductor memory device, comprising:
a memory cell array comprising a plurality of memory cell rows, each row of the plurality of memory cell rows comprising a plurality of volatile memory cells; and
a refresh control circuit configured to perform a refresh operation on the plurality of memory cell rows,
wherein the refresh control circuit comprises a hammer address register, and
wherein the refresh control circuit is further configured to:
receive a first active signal corresponding to a first active command received from an external memory controller at a first time point;
generate a counted value by counting active signals corresponding to active commands received until the first time point;
generate a multiplied value based on a multiplication operation on the counted value and first upper bits corresponding to a portion of a random binary code;
selectively store, based on comparing the multiplied value with a reference value, a first access row address corresponding to the first active command in the hammer address register; and
perform a hammer refresh operation, at a refresh timing, on one or more victim memory cell rows corresponding to a hammer address output from the hammer address register, the one or more victim memory cell rows being physically adjacent to a memory cell row from among the plurality of memory cell rows.

2. The semiconductor memory device of claim 1, wherein the refresh control circuit further comprises:
a hammer refresh circuit configured to perform the hammer refresh operation; and
a refresh control logic circuit configured to:
generate a hammer refresh enable signal based on a refresh command received from the external memory controller; and
provide the hammer refresh enable signal to the hammer refresh circuit, and
wherein the hammer refresh circuit comprises:
a counter configured to generate the counted value by counting the active signals received until the first time point;
a random bit generator configured to generate the random binary code based on a clock signal;
a multiplier circuit configured to generate the multiplied value based on the multiplication operation on the counted value and the first upper bits of the random binary code;
a comparison circuit configured to compare the multiplied value with the reference value, to generate an updating signal based on a result of the comparison, and to provide an update signal to the hammer address register; and
a mapper configured to output hammer refresh addresses designating addresses of the one or more victim memory cell rows based on the hammer address output from the hammer address register.

3. The semiconductor memory device of claim 2, wherein the random bit generator is further configured to generate the random binary code comprising M bits, M being a positive integer greater than three,
wherein the counter is further configured to generate the counted value comprising N bits, N being a positive integer less than M, and
wherein the multiplier circuit is further configured to:
generate a sub multiplied value by performing the multiplication operation on the counted value and the first upper bits of the random binary code;
generate an excess bit by performing operation on second upper bits corresponding to a portion of the first upper bits and third upper bits of the counted value; and
provide, to the comparison circuit, the sub multiplied value and the excess bit as the multiplied value.

4. The semiconductor memory device of claim 3, wherein the reference value corresponds to a maximum value of the random binary code; and
wherein the comparison circuit is further configured to determine a logic level of the updating signal at the first time point based on a logic level of the excess bit and the sub multiplied value.

5. The semiconductor memory device of claim 4, wherein the comparison circuit is further configured to:
based on the excess bit having a first logic level and the sub multiplied value being a non-zero value, determine that the multiplied value is greater than the reference value and output the updating signal with a second logic level at the first time point.

6. The semiconductor memory device of claim 5, wherein the hammer address register is further configured to:
based on the updating signal having the second logic level, maintain a hammer address that is pre-stored therein.

7. The semiconductor memory device of claim 4, wherein the comparison circuit is further configured to:
based on the excess bit having a first logic level and the sub multiplied value being a zero value, determine that the multiplied value is less than or equal to the reference value and output the updating signal with the first logic level at the first time point.

8. The semiconductor memory device of claim 7, wherein the hammer address register is further configured to:
based on the updating signal having the first logic level, update a hammer address that is pre-stored therein with the first access row address.

9. The semiconductor memory device of claim 4, wherein the comparison circuit is further configured to:
based on the excess bit having a second logic level, determine that the multiplied value is less than or equal to the reference value and output the updating signal with a first logic level at the first time point.

10. The semiconductor memory device of claim 9, wherein the hammer address register is configured to:
based on the updating signal having the first logic level, update a hammer address that is pre-stored therein with the first access row address.

11. The semiconductor memory device of claim 3, wherein the multiplier circuit comprises:
a plurality of AND gates configured to perform an AND operation on each of the first upper bits and respective one of N bits of the counted value;
a plurality of full adders configured to generate the sub multiplied value by performing adding operation based on outputs of the plurality of AND gates; and
an excess bit generator configured to generate the excess bit by performing operation on the second upper bits and the third upper bits.

12. The semiconductor memory device of claim 2, wherein the counter is further configured to:
reset the counted value based on the hammer refresh enable signal.

13. The semiconductor memory device of claim 12, wherein the counter is further configured to:
receive the hammer refresh enable signal at a second time point prior to the first time point; and
count a number of the active signals received from the second time point to the first time point.

14. The semiconductor memory device of claim 2, wherein the hammer refresh circuit further comprises:
a control logic circuit configured to provide a pop signal to the hammer address register based on a refresh management signal that is based on the refresh command, and
wherein the hammer address register is further configured to output a hammer address to the mapper based on the pop signal.

15. The semiconductor memory device of claim 14, wherein the refresh control logic circuit is further configured to generate a hammer refresh signal based on the refresh management signal, and
wherein the mapper is configured to output the hammer refresh addresses based on the hammer refresh signal.

16. The semiconductor memory device of claim 2, wherein the random bit generator is further configured to:
generate the random binary code having an integer value between zero and 2^{M}−1 by using a linear feedback shift register, M being a positive integer greater than three, and
wherein the reference value corresponds to 2^{M}−1.

17. The semiconductor memory device of claim 16, wherein the multiplier circuit is further configured to:
generate a sub multiplied value by performing the multiplication operation on the counted value and the first upper bits of the random binary code; and
generate an excess bit by performing operation on second upper bits corresponding to a portion of the first upper bits and third upper bits of the counted value, and
wherein the comparison circuit is further configured to:
determine a logic level of the updating signal by comparing the multiplied value comprising the sub multiplied value and the excess bit with the reference value;
output the updating signal with a first logic level based on determining that the multiplied value is greater than the reference value; and
output the updating signal with a second logic level based on determining that the multiplied value is less than or equal to the reference value.

18. A semiconductor memory device, comprising:
a memory cell array comprising a plurality of memory cell rows, each row of the plurality of memory cell rows comprising a plurality of volatile memory cells;
a refresh control circuit configured to perform a refresh operation on the plurality of memory cell rows; and
a row hammer management circuit comprising a hammer address register,
wherein the row hammer management circuit is configured to:
receive a first active signal corresponding to a first active command received from an external memory controller at a first time point;
generate a counted value by counting active signals corresponding active commands received until the first time point;
generate a multiplied value based on multiplication operation on the counted value and first upper bits corresponding to a portion of a random binary code;
selectively store, based on comparing the multiplied value with a reference value, a first access row address corresponding to the first active command in the hammer address register; and
output a row address stored in the hammer address register to the refresh control circuit as a hammer address, and
wherein the refresh control circuit is further configured to:
perform a hammer refresh operation, at a refresh timing, on one or more victim memory cell rows corresponding to the hammer address, the one or more victim memory cell rows being physically adjacent to a memory cell row from among the plurality of memory cell rows.

19. The semiconductor memory device of claim 18, wherein the row hammer management circuit further comprises:
a counter configured to generate the counted value by counting the active signals received until the first time point;
a random bit generator configured to generate the random binary code based on a clock signal;
a multiplier circuit configured to generate the multiplied value based on the multiplication operation on the counted value and the first upper bits of the random binary code;
a comparison circuit configured to compare the multiplied value with the reference value, generate an updating signal based on a result of the comparison and provide an update signal to the hammer address register; and
a refresh control logic circuit configured to provide a pop signal to the hammer address register based on a refresh management signal that is based on a refresh command provided from the external memory controller, and
wherein the hammer address register is configured to output the hammer address to a mapper based on the pop signal.

20. A memory system, comprising:
a semiconductor memory device; and
a memory controller configured to control the semiconductor memory device and to apply a refresh command to the semiconductor memory device,
wherein the semiconductor memory device comprises:
a memory cell array comprising a plurality of memory cell rows, each row of the plurality of memory cell rows comprising a plurality of volatile memory cells; and
a refresh control circuit configured to perform refresh operation on the plurality of memory cell rows,
wherein the refresh control circuit comprises a hammer address register, and
wherein the refresh control circuit is further configured to:
receive a first active signal corresponding to a first active command received from the memory controller at a first time point;
generate a counted value by counting active signals corresponding active commands received until the first time point;
generate a multiplied value based on multiplication operation on the counted value and first upper bits corresponding to a portion of a random binary code;
selectively store, based on comparing the multiplied value with a reference value, a first access row address corresponding to the first active command in the hammer address register; and
store a first row address randomly selected from the first access row address in a hammer address queue as a first candidate hammer address; and
perform a hammer refresh operation, at a refresh timing, on one or more victim memory cell rows corresponding to a hammer address output from the hammer address register, the one or more victim memory cell rows being physically adjacent to a memory cell row among the plurality of memory cell rows.
